(19) United States
(12) Patent Application Publication
(10) Pub. No.: US 2016/0003344 A1
(43) Pub. Date: Jan. 7, 2016

(54) CONSTRUCTIONS FOR LOAD-BEARING STRUCTURES; ADVANTAGEOUS METAL-PLASTIC COMPOSITE CONSTRUCTIONS; METHODS OF PREPARATION AND ASSEMBLY; SYSTEMS AND METHODS

(71) Applicant: EATON CORPORATION, Cleveland, OH (US)

(72) Inventors: Javed Abdurrazzaq MAPKAR, Commerce Township, MI (US); Kelly Ann WILLIAMS, South Lyon, MI (US)

(21) Appl. No.: 14/854,511

(22) Filed: Sep. 15, 2015

Related U.S. Application Data
(63) Continuation of application No. PCT/US2014/025696, filed on Mar. 13, 2014.
(60) Provisional application No. 61/852,139, filed on Mar. 15, 2013.

(51) Int. Cl. F16H 57/032; F16H 57/037; H05K 5/02; G06F 17/50

(52) U.S. Cl. CPC F16H 57/032; G06F 17/50; F16H 57/037; H05K 5/0217; F16H 2057/0087

(57) ABSTRACT

Improved hybrid construction and techniques for forming them are described. They are particularly applicable to generate load-bearing structures. Examples described include load-bearing housings. Methods of preparation, assembly and systems of methods of use are described.

### CROSS REFERENCE TO RELATED APPLICATION

This application is a Continuation of PCT/US2014/025696 filed on 13 Mar. 2014, which claims benefit of U.S. Patent Application No. 61/852,139 filed on 15 Mar. 2013, and which applications are incorporated herein by reference. To the extent appropriate, a claim of priority is made to each of the above disclosed applications.

### FIELD OF THE DISCLOSURE

The present disclosure relates to techniques, features and components especially applicable with respect to various load-bearing structures. Examples of such structures include: equipment housings such as transmission housings; differential housings, clutch housings; pump housings; electrical enclosures; and, circuit breaker boxes; and, various equipment configurations such as gearing systems, for example transmission gearing systems.

The techniques relate to providing such structures, which often have comprised 100% (or nearly 100%) structural metal components, with load-bearing componentry comprising a combination of metal components and plastic components, i.e. with hybrid constructions. Such approaches can be applied to provide substantial savings with respect to weight, and, in some applications, cost. They can also be applied to achieve advantageous equipment configurations. Methods and techniques for accomplishing this are described.

### BACKGROUND

Metal parts, for example cast iron or steel parts, are used in a variety of equipment types, in which substantial load-bearing is encountered. Examples include: differential housings, transmission housings, clutch housings; and, pump housings. Metal is used in a variety of other enclosures such as electrical enclosures (for example circuit breaker boxes). Also, metal parts (for example cast steel or iron) are used in a variety of components such as gearing systems. Such components can be expensive and relatively heavy. It is generally desirable to reduce the weight of such components, in a variety of applications. For example, reduction in weight of components used in vehicles, can lead to greater fuel efficiency and other advantages. Reduction in weight of components can also lead to: cost savings, for example in shipping and handling of the component, and in convenience for installation, service and equipment assembly.

In some fields, weight reduction has been implemented through shifting of material from iron or steel to lighter weight metal materials such as aluminum or various light-weight metal alloys. However, these can be relatively expensive and are not always desirable in many high volume, relatively lower cost, applications, such as in the construction of equipment and components for land vehicles; for example in transmission housings and/or differential housings. In addition, further weight savings are often desired.

It is desirable to provide techniques for such weight and cost savings applicable to systems in which the load-bearing components are generally formed from metal. It is particularly desired to conduct such weight savings when the metal parts are iron or steel. It is noted, however, that sometimes weight savings are desirable even when the load-bearing component is of a light weight metal, such as aluminum, and the techniques described herein can be used to accomplish this.

### SUMMARY

According to the present disclosure, techniques features and components, especially applicable with respect to various load-bearing structures (structural components) are provided. The techniques generally relate to constructing certain types of (typically load-bearing) structures or components as hybrid structures (or structural components) formed from metal (often iron or steel) and an applied plastic material, typically a reinforced plastic (composite) material.

The techniques generally involve forming selected portions of a target load-bearing structure or component from metal, in locations for which load-bearing analyses (and/or experience) have shown relatively high load-bearing occurs. Other portions, however, are provided from plastic, at locations for which load-bearing analysis (and/or experience) show(s) less load-bearing occurs. The result is referenced herein as a “hybrid” component, assembly or system.

Example systems for advantageous application of the techniques is possible, can involve housings, such as load-bearing housings used as: differential housings; transmission housings; clutch housings; and/or pump housings. The techniques can be applied, for example, in other types of enclosures, for example electrical enclosures.

In addition, load-bearing parts of systems that are not themselves housings, can be constructed as hybrid parts using techniques according to the present disclosure. For example, the techniques can be applied to provide components of gearing systems.

Typically, the techniques will be particularly advantageous when applied in application in which at least portions of the load-bearing structure are required to be capable of bearing loads of at least 1000 N (Newtons); typically at least 1500 N and often substantially more.

### BRIEF DESCRIPTION OF THE DRAWINGS

FIG. 1 is a schematic side elevational view of a prior art housing comprising selected metal components.

FIG. 2 is a schematic perspective depiction of the prior art housing of FIG. 1.

FIG. 3 is a schematic exploded view of the prior art housing depicted in FIGS. 1 and 2.

FIG. 4 is a schematic side view of an improved hybrid component arrangement according to the present disclosure.

FIG. 5 is a schematic exploded perspective view depicting cast metal and molded plastic components or sections of the hybrid component arrangement of FIG. 4.

FIG. 6 is a schematic isometric view of a first metal portion of the hybrid component arrangement depicted in FIG. 4.

FIG. 7 is a schematic side elevational view of a first section of the component arrangement depicted in FIG. 4.

FIG. 8 is a schematic isometric view of a cast metal portion of a second section of the component arrangement depicted in FIG. 4.

FIG. 9 is a schematic isometric view of a molded plastic portion of a second section of the component arrangement depicted in FIG. 4.

FIG. 10 is a schematic representation of selected experimental conditions and parameters for a six pinion differential housing described in a working example herein.

FIG. 11A is a first view of a first schematic structure diagram in accord with a working example described herein.

FIG. 11B is a second view of the first schematic structure diagram of the working example characterized in FIG. 11A and described herein.

FIG. 11C is a first view a second schematic structure diagram in accord with the working example described herein.

FIG. 11D is a second view of the schematic structure diagram characterized in FIG. 11C.

FIG. 12A is a fragmentary, schematic, first view of a first design concept developed in a working example described herein.

FIG. 12B is a schematic second view of the first design concept developed in the working example discussed herein.

FIG. 13A is a fragmentary schematic first view of a second design concept developed in accord with the working example described herein.

FIG. 13B is a schematic second view of the second design concept described in the working example herein.

FIG. 14A is a fragmentary schematic first view of a third design concept characterized in a working example herein.

FIG. 14B is a schematic second view of the third design concept described in the working example herein.

FIG. 15A is a schematic view first component of a selected design described in the working example herein.

FIG. 15B is a schematic view of second component of the working example described herein.

FIG. 15C is a schematic view third component of the working example described herein.

FIG. 15D is a schematic view of a hybrid component of a working example, that results from the assembly of the fraction components described in connection with FIGS. 15A, 15B and 15C.

FIG. 16A is a schematic depiction of a second component of the working example.

FIG. 16B is a schematic depiction of a selected component section of the component of FIG. 16A.

FIG. 16C is a schematic depiction of a second component section of the working example represented by FIG. 16A.

### DETAILED DESCRIPTION

### I. General Principles; Example System for Implementation

### A. General Principles

According to the present disclosure, techniques are provided to improve previously fully (or nearly fully) metal (typically iron or steel, but sometimes other metal such as aluminum) equipment components (structural components). The improvements relate to providing selected portions of the (structural) components from plastic, i.e. as a molded plastic material, as opposed to metal, resulting in a hybrid (metal/plastic) construction. The techniques can be applied to provide for substantial weight savings. Through the weight savings, the applications can be applied to provide for cost, transport, assembly and use advantages. Also, the techniques can be applied to provide advantageous equipment configurations.

The described techniques can be applied in a wide variety of systems. Examples include load-bearing housings for various types of equipment. For example, housings such as transmission housings, differential housings, clutch housings, pump housings and other gearing housings can be improved by the techniques described. Also, other housings such as electrical enclosures can be improved with the techniques herein. The techniques, however, are not limited to housing applications, and can be used for componentry such as load-bearing gearing components, etc.

The amount of weight advantage that can be gained by applying the techniques of the present disclosure is a matter of choice for a given system, and need not be fully optimized to obtain some advantage. When comparing components for the same application, typically when the first comprises a prior art (often cast) metal (for example iron or steel) system or component and a second comprises a hybrid system or component improved according to the present disclosure, a weight savings (decrease) for the improved (hybrid) component relative to the prior (metal) component of at least 10% will typically be considered significant. In many applications, direct weight savings on the order of at least 15% and in some instances 20% or more, for example 20% to 45% can be obtained in some applications. When the referenced weight comparison is made, the intent is to directly compare the portion(s) now made hybrid (plastic/metal) with the analogous fully metal component(s) replaced by the hybrid.

In general, the techniques relate to identifying substrate components or systems for which improvement is desired. Components of the chosen systems are analyzed for portions of the previously metal construction that can be relieved of metal with, in some instances, the removed metal replaced with molded lighter weight (plastic) material. Once these portions are identified, construction results from: generating a metal portion without the selected (identified) section(s); and, then, securing-in-place (typically by molding-in-place) the plastic composite section(s) to provide whatever closure or strength operation is needed in those selected sections and to result in the hybrid component.

As an example, consider a housing that operates to contain gearing or other equipment. Examples are vehicle transmission housings and differential housings. The selected housing can be identified as having key load-bearing sections; and/or, key sections made to strict tolerance(s) for the application intended. The housing can also be evaluated for distribution of load during operation of the equipment. Sections of the housing that: are not subject to high load-bearing; and/or, load distribution; and, which are not critical, for example with respect to tolerance(s), are portions that are candidates to be made devoid of metal and, for example, to be replaced with molded plastic (composite) material in accord with techniques herein, to create a hybrid construction in accord with the present disclosure. In the next section, a practical example is discussed.

### B. An Example Equipment Arrangement

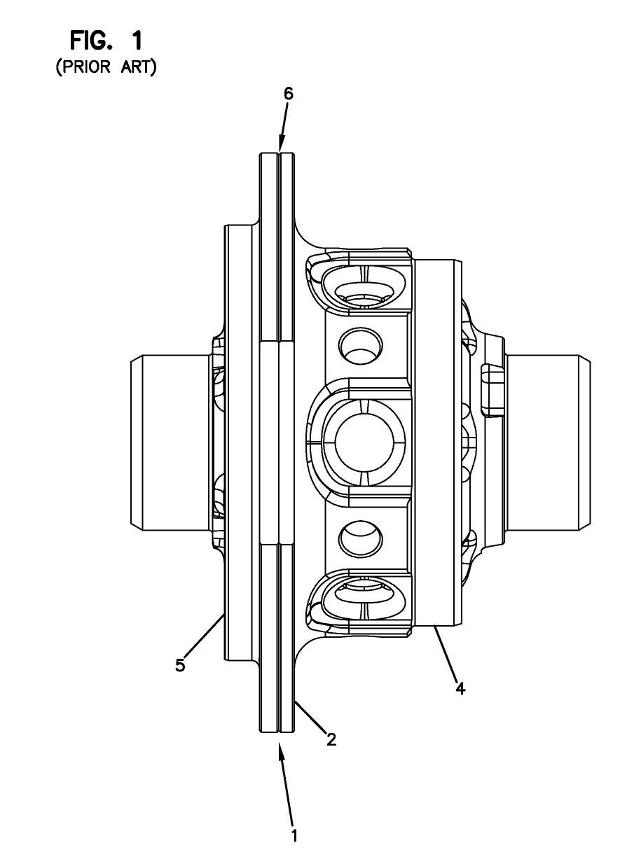

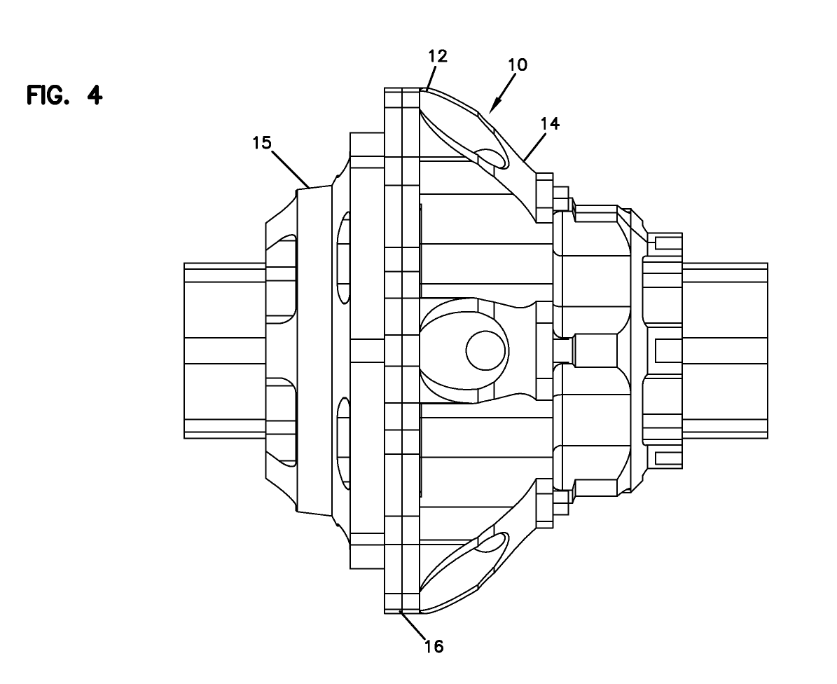

In FIGS. 1-3, an equipment system or arrangement made of metal components is depicted. In FIG. 4, an equipment system or arrangement for analogous use, but which comprises hybrid constructions of metal and plastic component is depicted. In FIGS. 5-9, depictions of portions of the equipment arrangement of FIG. 4 are shown.

For demonstration of the principles of the present application, an example equipment (component) system is selected that is a housing. The specific housing depicted is a differential housing; i.e. a housing that encloses gearing systems and equipment for operating as a vehicle differential, and which, in use, has various components mounted thereon. The demonstrated equipment is meant to be exemplary only. The techniques can be applied in a variety of alternate housings; and, in equipment arrangements that are not themselves housings.

Referring first to FIG. 1, a side elevational view of a component or equipment arrangement 1 is depicted. It is noted that the arrangement 1 is depicted without other componentry related to its operation, and without exterior bolts or other constructions that would be used to secure the arrangement 1 together. The particular arrangement 1 depicted in FIG. 1 is an equipment housing 2 that could be used, for example, as part of C510 differential, such as made by Eaton, the Assignee of the present disclosure.

Thus, referring to FIG. 1, a load-bearing metal component 1 is depicted suitable for application of the techniques described herein. The load-bearing metal component 1 in the example depicted comprises a housing 2, formed from two separately constructed metal components 4, 5, joined to one another at interface 6. When the housing 2 is a differential housing, generally the joining at interface 6 is by bolts or similar connector arrangements, typically with a gasket arrangement, not depicted, between the parts 4, 5.

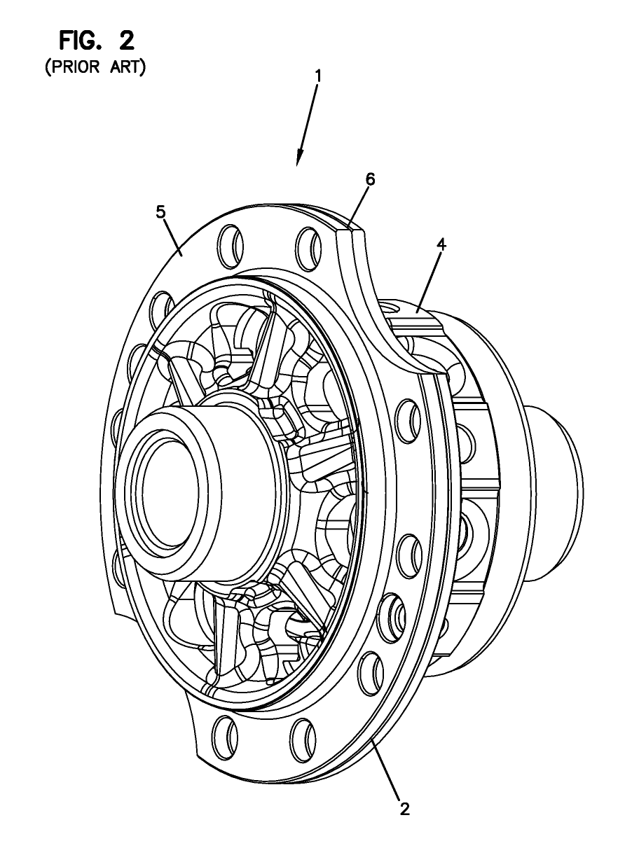

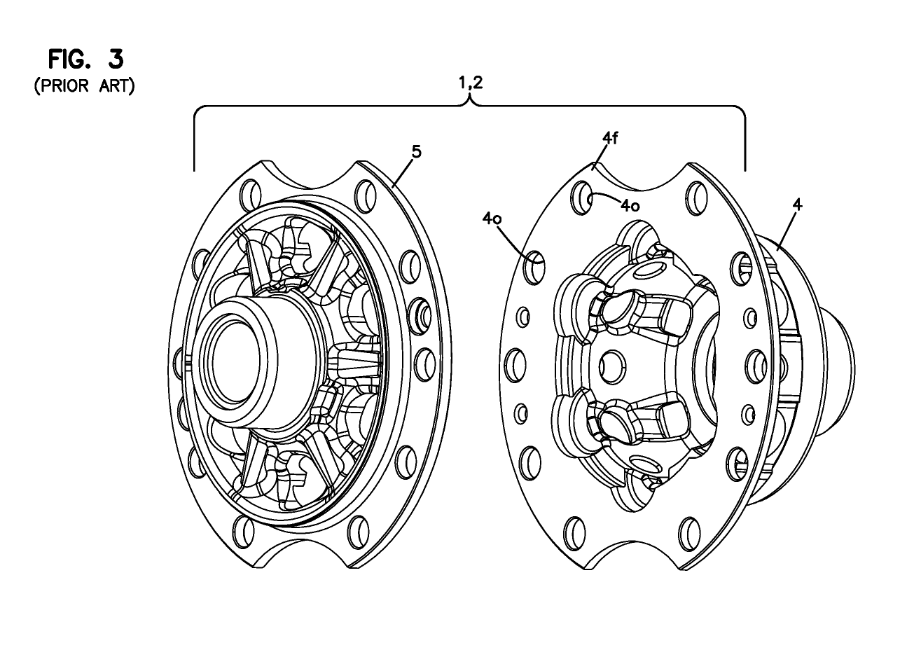

In FIG. 2, the arrangement 1, i.e. housing 2, is depicted in perspective view. In FIG. 3, an exploded perspective view is provided, allowing first and second components 4 and 5 to be individually viewed.

Each of the components 4, 5, would, prior to the present application of techniques, be a metal component. Often the component would be an iron or steel component, but in some instances it could be an alternate metal, for example an aluminum component. In many instances, the component will have been made from cast metal, although the techniques described herein can be applied in other types of metal systems, for example, stamped metal systems. The components 4, 5 can be fairly heavy. This makes component formation, transportation, assembly, installation and use more difficult and somewhat more expensive. In addition, it adds weight to the eventual system in which the component is used, for example a vehicle, which raises issues of cost, fuel use, and additional component construction issues.

From the information of the previous paragraphs, it can be understood that the particular example housing 1 depicted in FIGS. 1-3 is a relatively small housing, weighing 1.5-5 kg. Differential and/or transmission housings for larger equipment can weigh substantially more, for example 20-70 kg for the housings alone. With such larger housings, relatively large weight savings can be accomplished for the techniques described herein, as will be understood from descriptions further below.

According to the present disclosure, an arrangement such as arrangement 1 is evaluated for which sections or portions can be formed from plastic (composite) material as opposed to being from the metal. The techniques are then applied to provide a hybrid replacement component, which is partially metal and which is also partially molded plastic component. This provides weight savings and related advantages. In FIG. 4, such an arrangement 10, for replacement of arrangement 1, through application of the advantageous techniques described herein, is provided in side elevational view.

The arrangement 10, then, comprises a replacement housing 12 for the housing 2. The housing 12 comprises first and second components or sections 14, 15 joined at interface 16. The joining of sections 14, 15 at interface 16 would generally be secured with bolts or other fasteners, and be provided with appropriate gasketing, when the housing 12 is assembled to form a working component. The housing 12 would typically weigh about 1.7 to 1.8 kg, when formed as described; and, would, provide a weight reduction of at least 40-50% relative to the housing 2 (which would weigh 3.3 kg in an example Eaton cast iron C510 differential.

In general, weight savings with respect to housing definition, by application of the techniques herein, can be on the order of at least 10%, often at least 15%. Indeed in many instances, it will be 20-45% or more. This will be the case when the housing or housing component being modified has a weight, when made from metal, on the order of at least 1.5 kg, and typically if it is within the range of 3-70 kg.

Applications of the principles described herein can be understood, in part, by reference to FIG. 5. In FIG. 5, an exploded perspective view of the housing 12 is depicted. The first section 14, FIG. 4, would be formed from sections of materials as indicated at 14 in FIG. 5. The second section 15 would be formed from the material sections indicated generally at 15, FIG. 5.

Referring first to section 14, FIG. 5, in the completed hybrid housing 12, hybrid section 14 would comprise a metal portion indicated at 20 and molded (plastic composite) portions indicated at 21, 22 and 23. The plastic composite portions 21, 22 and 23 would comprise lighter weight materials (and sometimes lower cost materials on a weight basis) than the metal of component 20, relating to advantage.

It is noted that in actual manufacture of hybrid component 14, the sections 21, 22 and 23 will typically not be separately made. Rather, metal portion or section 20 is first made, for example it is typically cast or stamped and then machined to specification although alternatives are possible. Then, in a typical application, plastic composite sections which are separated would be in accord with 21, 22 and 23 (for example in a single compression molding application) to provide sections 21, 22 and 23, integral with one another, added to metal section 20. This would result in section 14, FIG. 4.

Still referring to FIG. 5, for structure 15, the metal section is indicated at 30 and the molded plastic composite section at 31. In a typical application, these would not be separately constructed, rather in a typical application of the techniques, section 30 would be formed; and, then, section 31 would be formed on section 30, for example using compression molding techniques.

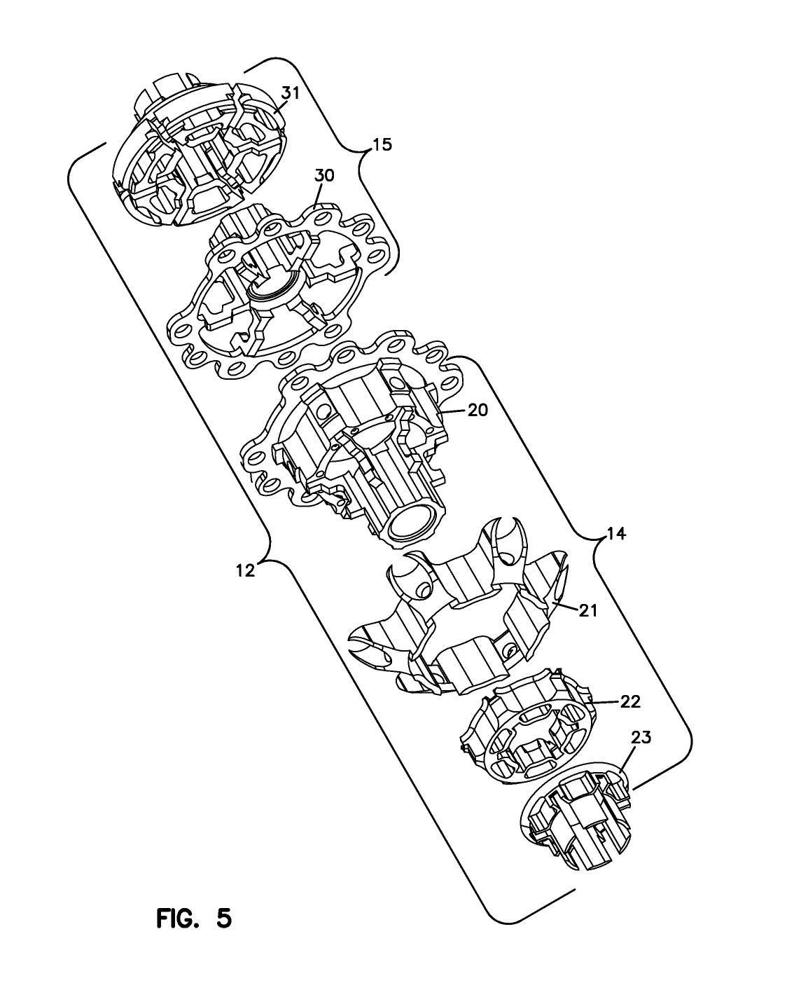

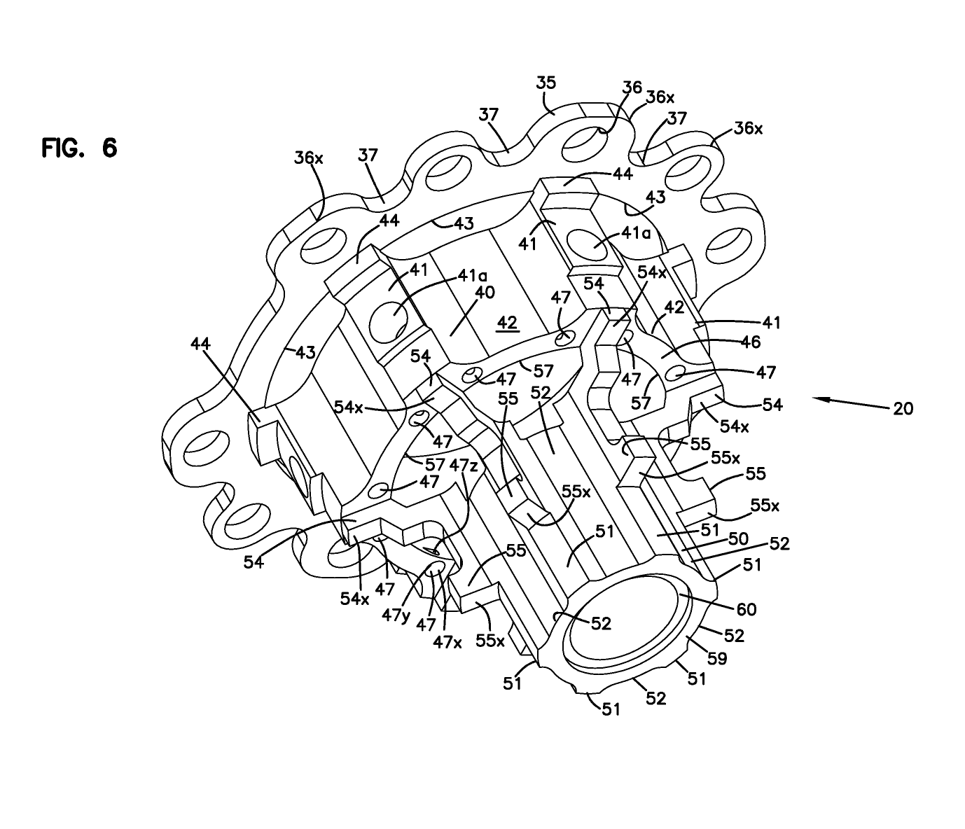

Attention is now directed to a comparison of metal section 4, FIG. 3 and metal section 20, FIG. 6. Assuming the related housings (2, 12) are intended for the same use and to contain and support the same componentry, a comparison of sections 4 and 20, each of which would be made from metal, allows for a comparison of the parts for reduction in weight. In general, substantially less metal is included in section 20 than in section 4. The plastic composite material selected for the molded composite sections 21, 22 and 23 can be selected such that it is very light relative to the sections removed from equipment section 4 to provide metal section 20. Thus, the overall hybrid component 14 can be provided with less weight (relative to component 4). In addition, because, in the example chosen, non-metal sections of the resulting hybrid component 14 are molded on the exterior, the exterior can be provided with unique and advantageous shape and surface features: e.g. decorative or informational features; and/or light-weight plastic sections to provide advantage in use, such as conveniently shaped to accommodate the environment of installation, etc. A similar comparison can be made between housing section 5 and metal section 30 of housing hybrid section 15.

Issues relating to development of a replacement hybrid structure (metal/plastic structure) for component 10 for replacing component 1 concern which portions of the metal should be relieved of some metal or be eliminated entirely, and be which should be provided with molded plastic composite, i.e. substantially lighter material. While a variety of techniques to affect this can be used, in general, a cost-effective approach includes applying the following general principles:
1. Retain, in metal, portions that relate to fastening components together, for example which operate as bearing surfaces for bolts or other fasteners, and/or as supports for bearings, gears, bushings, or other portions of the equipment.
2. Retain, in metal, portions that need to be machined to high specificity (very specific tolerances) for proper assembly and operation of the equipment.
3. Retain, in metal, portions over which a substantial amount (i.e. above a selected amount) of load-bearing, in use, is distributed.

An example of application of these principles can be understood by comparing section 4, FIGS. 1, 2 and 3, with the metal section 20 of the housing hybrid section 14, FIG. 6. For example, in FIG. 3, section 4 can be seen as having a mounting flange 4f, with apertures 4o therein, for bolts. Metal section 20, FIG. 6 has been configured to retain a metal flange 35 with apertures 36 therein, for bolts or fasteners. It is noted, however, that some unnecessary metal has been removed in flange 35 by providing recesses 37 between sections 36x, through which apertures 36 extend. Recesses 37 represent areas where excess metal is not needed for any purpose, and thus is removed relative to flange 45, FIG. 3.

It should be understood that the entire component 20, FIG. 6, is configured as a metal piece, typically iron or steel (later machined is selected areas) depending on the application. Component 20, for example, can be a cast metal piece that has been machined, but alternatives are possible. Flange 35 is a mounting flange having apertures 36 therein; the flange 35 being configured to mate with a corresponding flange of a separate housing hybrid component 15 discussed below. The flange 35 needs to be very strong, to manage the bearing load of bolts or other fasteners, during assembly of the equipment. It also needs to support other portions of the resulting hybrid component 14, in the overall housing assembly 12, and it bears substantial loads in use.

Integrally connected to flange 35 is provided a first housing/hub portion or section 40. The housing/hub portion or section 40 surrounds enclosed components. Section 40 includes a plurality of alternating thick sections 41 and thin sections 42. (In the context of this example, thickness if in reference to a dimension through the metal from in-to-out, or out-to-in, i.e. toward or away from a central axis of the section 40).

The thick sections 41 are sections of the housing/hub section 40 that have been identified as bearing sufficient load therein, during operation of the equipment involving housing 12, to warrant substantial metal in these regions. For example, attention is directed to apertures 41a in regions 41. In the resulting equipment, these apertures support shafts of pinion gears, in assembly. These are not only locations where substantial strength is needed to do the load-bearing, but the apertures 41a themselves typically need to be constructed to very specific, and tightly managed, tolerance requirements. Thus sections 41 are preferably metal (later machined) and relatively thick. Sections 42, on the other hand, are relatively thin, by comparison to sections 41, since it has been determined that they do not have as great a load-bearing or load distribution operation in the resulting equipment. However, it has been determined that they have a sufficient load-bearing function to warrant comprising metal.

In a typical application of the principles herein, when applied to a housing that has a housing/hub section 40, having relatively thick sections 41 and relatively thin sections 41, for example alternating, the thinnest portion of the thin sections is typically no more than 85% of the thickest portion of the thick sections, usually no more than 70% and sometimes no more than 60%.

Regions 43, of component 20, FIG. 6, are devoid of metal. These are sections for which it has been determined that the load-bearing capability of metal is not needed at all. Thus, in the final equipment assembly, if all that is needed is that these regions 43 be closed or be provided with material of limited or minimal load-bearing capability, for example, regions 43 can be closed by plastic composite material, for example overmolded in place as discussed herein.

Regions 44 are transition or attachment sections located where the housing/hub portion or section 40 engages the flange 35. These will be regions of high load-bearing, since these are the locations where the flange 35 supports the housing/hub section 40 and remainder of the section 20. In region 44, all load-bearing from the section 40 is transferred to the flange 35. Thus, in regions 44 the relatively thick metal sections 41 engage the flange 35.

Attention is directed to end 46 of the first housing/hub perimeter section 40. End 46, which is an end remote from mounting flange 55, includes a plurality of apertures 47 therein. Referring to an example aperture 47x, it can be seen that apertures 47 allow for a complete flow (through a portion of hub 40) of composite resin when plastic is molded onto the component 20 to provide the hybrid component 14. In particular and referring to aperture 47x, it can be seen that the particular aperture 47x extends between opposite ends 47y, 47z in hub 40. Thus a “tunnel” or “bore” is created through which plastic composite resin can flow during the overmolding process described herein. It is noted that the particular apertures 47 are bores that do not communicate with an opposite side (in this instance, an interior) of the housing 10 but rather have opposite ends that only terminate at one (in the example, outer) surface portion of section 20, in this instance housing/hub portion 40.

In more general terms, portions of metal component 20 can be provided with one or more anchor sites for the molded (plastic composite) portions of the resulting hybrid component 14. These anchor sites, can, for example, comprise flow-through sections (or anchor bores) generated in the metal of the component 20, for example: not in communication with both of the possible surfaces (inner and outer) of the resulting housing, but only in communication with one surface and through which can flow resin to obtain an anchor for the molded material. In general, the term “anchor site” (and variants) is meant to be any site which facilitates a mechanical interlock between the molded plastic and the metal (other than mere surface roughening of the metal). As will be apparent from the descriptions herein, the anchor sites can take on a variety of configurations. In some systems, an advantageous configuration will be as an anchor bore, with opposite open ends communicating with the same surface (inner or outer) of the metal component 20. Apertures 47 comprise this latter type of anchor site.

As explained above, housing/hub section 40, for the example component 20 depicted, is an intermediate section which provides for joining of remaining sections of the component 20 to the flange 35. The remaining section of component 20 is generally an end hub section depicted at 50. The end hub section 50 can be viewed as having a plurality of radially alternating thick sections 51 and thin sections 52. Together, the hub section 40 and hub section 50 comprise a metal, hub, portion of housing section 14 secured to flange 35, FIG. 6.

The distribution of thick sections 51 and thin sections 52 reflects, analogously to section 40, the result of load-bearing analyses on the equipment 12 and ensuring that metal portions of section 20 are distributed to manage that load-bearing in a preferred manner. Thus, sections 51 are thicker because they are sections that relate to where load-bearing is most concentrated in use. Sections 52 provide for structural integrity but are less critical to the management of load-bearing.

Referring to sections 51, attention is directed to regions 54, which comprise interface regions between hub section 50 and hub section 40. Regions 54 are relatively thick, because they are portions of section 51 that are the locations where load-bearing is transferred from housing/hub section 50 to housing/hub section 40. Surfaces 54x are also typically highly machined to very tightly controlled tolerance(s) and thus it is also advantageous that they be portions of metal.

Attention is now directed to regions 55 and surface 55x. These regions also bear substantial loads in use, and surfaces 55x are generally machined to a very tight tolerance to support additional mechanical structure(s), such as a speed ring or bearing ring.

Attention is now directed to spaces 57. Spaces 57, analogous to spaces 43, are devoid of metal. These are regions in which substantial load-bearing is not required. Thus, they are regions that can be closed by plastic composite, for example overmolded composite, because they are not generally required to possess the strength of metal sections. Also, when plastic is overmolded to section 50, there can be some mechanical interlock provided in the regions 57 where plastic can flow past portions of metal and develop a mechanical interlock or grip. Thus, selected edge portions of region 57 can be used as anchor sites, in this instance anchor sites that are in communication with an interior of housing 10.

Attention is now directed to end 59 of hub section 50; end 59 being an end of the metal component 20 remote from the flange 35. End 59 includes an aperture 60 therein which is typically machined to a very tight tolerance as it will support gearing and a rotating shaft, etc. in the final equipment. Thus, end 59 is important for lead bearing and for proper equipment operation, and is formed from the metal and not from plastic composite.

From the above, a general understanding of a first step in forming an advantageous equipment component, to replace a prior metal component, in accord with the present disclosure can be understood. The issues relate to replacing a previously (or theoretically) entirely metal component, with a component formed as a hybrid; i.e. a combination of a metal component and a plastic composite with the resulting advantages. In FIG. 6, an example metal component for use in such a hybrid structure is depicted. By comparison to the component 4 that it replaces, it can be understood that: metal has been removed from: regions where there was excess metal that is not required for proper operation (for example recesses at 37 in flange 35); and, regions that are not high load-bearing in the resulting equipment, for example sections 43 and 57; there is reduced amount of metal provided in other sections where high load-bearing is also not an issue; for example in sections 42 and 52. At the same time, metal is retained/concentrated in regions where there is high load distribution and/or where highly machined features (tight tolerance) are required, see for example regions 41 and 51, end 59 and regions adjacent apertures 41a, as well as platforms 54x, platforms 55x and aperture 60.

The example metal component 20 depicted further includes anchor sites or arrangements to facilitate securing the plastic component in place during operation. Selected anchor sites include bores or anchor bores 47, that extend completely through the metal, in this instance not in communication with an interior of the resulting of the housing, and through which plastic resin can flow during component formation. Other anchor sites include metal edges, for example edges to sections 57, over which or beyond which plastic can flow during molding, to generate a good connection to the metal.

Exterior surfaces or surface portions of component 20 can also be modified to facilitate securing of the (molded-in-place) plastic composite during molding. Techniques to accomplish this, for example, can be through abrasive treatment (i.e. mechanical treatment such as abrasion blast). In the alternative or in addition, the surface portions can be provided with a chemical adhesive, such as a silane, to facilitate adherence of the plastic composite during molding.

Construction of hybrid component 12 through the use of metal component 20 involves applying the plastic composite at the appropriate locations. A variety of techniques can be used to accomplish this. For example, this can be done by developing a mold appropriate for positioning of preformed component 20 therein, and overmolding plastic composite sections 21, 22 and 23, FIG. 5, of hybrid component 14. Typically the plastic composite component sections 21, 22 and 23 would be molded simultaneously within the mold, and plastic within them would be integral among them during the molding process. That is, sections 21, 22 and 23 would not typically need to be separately made, and they would not, in the final component hybrid 12, FIG. 4, typically need to be separable from (or spaced from) one another. They would also typically not be readily separable from hybrid component 20, once the molding (for example overmolding) occurs.

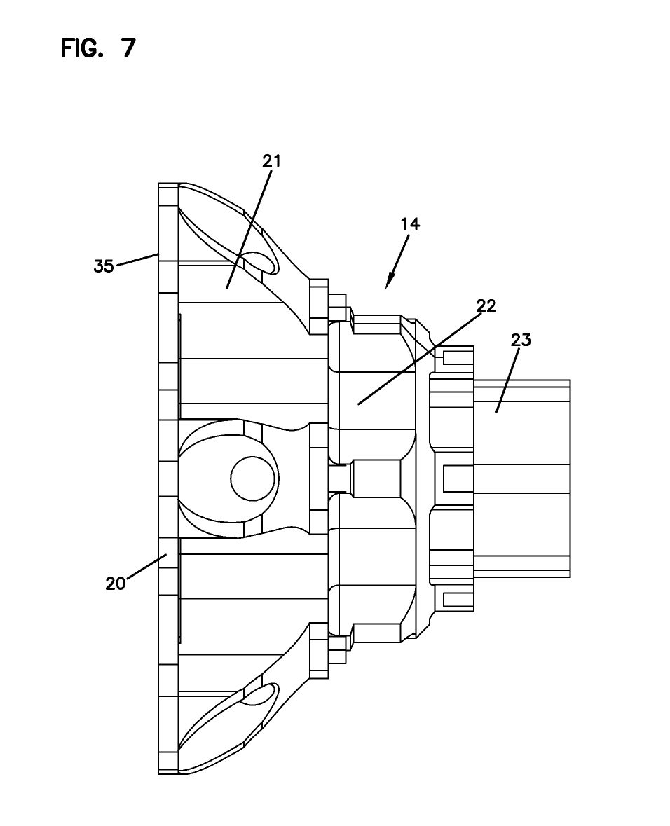

The resulting hybrid component 14 is depicted in FIG. 7. It can be seen that the plastic composite of sections 21, 22 and 23 has been overmolded on the metal component 20 sufficiently so that regions 43, 57, FIG. 6 are now closed. Also, the plastic material of sections 21, 22 and 23 is not located where bolts, pins or other equipment, that bear on portions of the metal component 14, are to be located.

Although not clearly visible in FIG. 7, as previously described, the plastic composite used in the formation of sections 21, 22 and 23: will have been allowed to flow through anchor sites or bores 47, FIG. 6, in the metal; and, in closing regions 57 it will have been allowed to flow over selected edges of the metal to facilitate anchoring of the plastic to the metal.

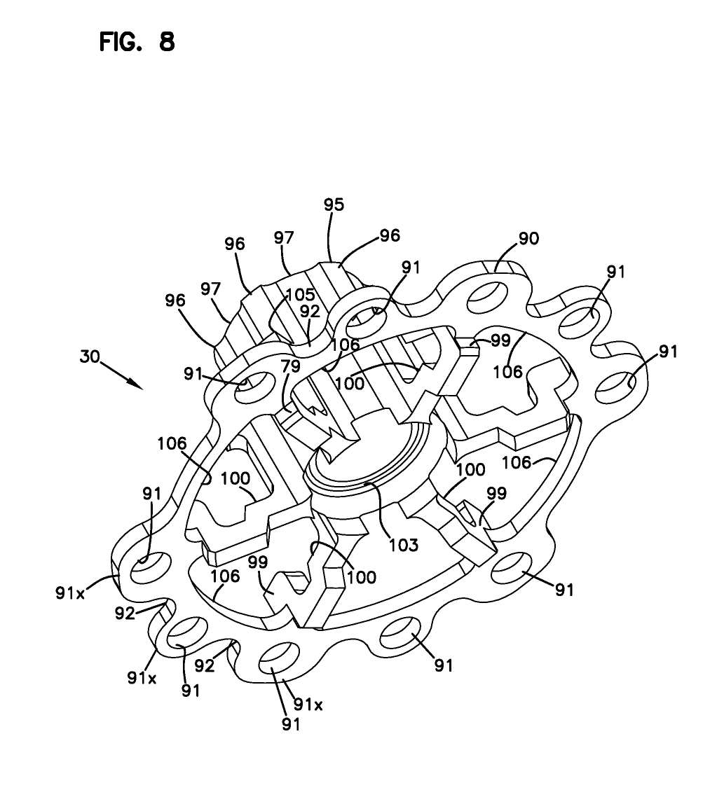

Referring again to FIG. 5, as previously discussed, housing hybrid section 15 would result from providing a metal component 30 and an overmold plastic composite component 31. The metal component 30 is viewable in FIG. 8, and, by analogy to component 20, component 30 can be readily understood.

Referring to FIG. 8, component 30 includes a mounting flange 90 providing for engagement with (or securement to) section 20, FIG. 5. The flange 90 includes a plurality of bolt (fastener) apertures 91 for this purpose. Recesses 92 in flange 90, between sections 91x including apertures 91, comprise sections devoid of metal so as to provide for a lighter weight flange 90.

The component 30 includes a metal housing/hub section 95 that provides for selected equipment support. Housing or hub section 95 comprises radially alternating thick sections 96 and thin sections 97. In general, the thick sections 96 are provided where load-bearing analysis shows that the greater load distribution will occur in the resulting component during use and thus substantial strength is provided. Sections 97 are regions in which less metal is provided, because less load-bearing occurs.

Housing/hub section 95 is secured to flange 90 at regions 99, integral with sections 95. Regions 99 are high load-bearing regions, since they transfer all load from hub section 95 to flange 90.

Sections 100 are sections that need to be manufactured to very tight tolerance for the particular equipment involved. Thus, these are located in sections of metal, in particular sections 99. Region 103 of hub section 97 is also machined to a very tight tolerance, as it relates to supporting of seal or bearing surfaces in the overall equipment. Thus, it too is located in a region of metal, devoid of plastic, for load-bearing purposes and machining (tolerance) purposes. Finally, regions 105, will also typically be regions of tight tolerance for the equipment involved. Regions 106 are devoid of metal, since the regions would not bear substantial load.

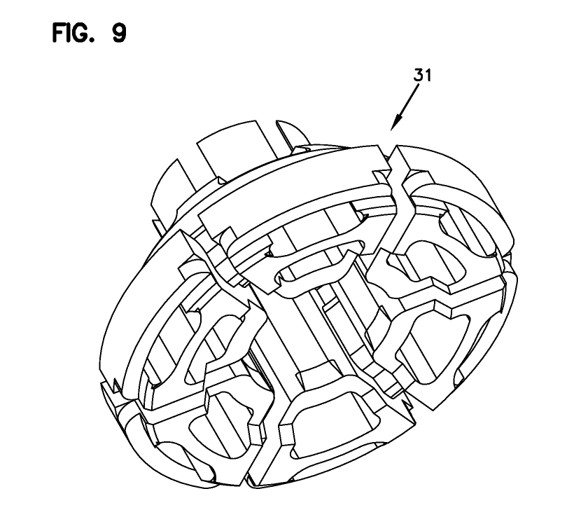

In FIG. 9, the overmolded plastic composite portion 31 is depicted. It can be seen that the plastic composite will fill in otherwise open portions 10b of the housing section 30, FIG. 8 of the resulting hybrid component 15. The plastic composite will provide additional strength in other sections, but generally is not used to provide the substantial strength needed in the high load-bearing sections of the resulting component. Some mechanical interlock can be provided during the overmolding, in selected regions where the plastic can flow over or past edges of the metal, and form mechanical interlock with anchor sites. The particular component 30, FIG. 8, depicted, does not include anchor bores. However, anchor bores could be used, if desired

### II. Determination of the Configuration of the Metal Components

A step in the application of techniques according to the present disclosure is determining which portions of the equipment of concern should comprise metal, and how much metal should be located in those portions. That is, for the example depicted above, an issue was the designing of the component sections 20, 30, which would be formed from metal.

General principles relating to this, referenced above, concern the following:
1. Providing metal (usually iron or steel, sometimes aluminum or alternate metal, often cast but not limited to cast) where substantial load-bearing occurs, such as in mounting flanges and sections for supporting high load or high strength equipment components in operation;
2. Ensuring that the metal component defines those surfaces or features that need to be maintained to a tight (specific) tolerance for proper equipment manufacture, assembly and operation;
3. Ensuring that adequate metal is distributed where substantial load-bearing during operation is distributed, for example where pinion supports, or bearings, bushings, and/or gear rings are located; and,
4. When appropriate, providing the metal component with appropriate features for mechanical engagement with the plastic during composite formation (for example, anchor sites).

Of course, the above principles need to be applied in the metal component in a manner that can be manufactured according to preferred process for the industry involved. For example, if the component is to be cast metal, it needs to be constructed with features consistent with the casting approach to be used.

Typically, techniques according to the present disclosure will be advantageously applied in systems which will have metal components that have first sections that need to bear loads of at least 1000 N, typically at least 1500 N, often at least 2500 N or greater, and, in many instances 3000 N or greater (sometimes substantially more, for example 25,000-65,000 N or more; and, for which it can be determined that there are also second regions that will have load-bearing requirements substantially lesser than in the first regions and in some instances in which second selected regions have substantial no load-bearing responsibility at all.

Typically a component for which applications according to the present techniques are effectively applied and will be a component having a weight of at least 1 kg, typically at least 1.5 kg and often at least 2 kg. In many instances, the component, when all metal, will weigh 15 kg, or more, for example 20 kg-120 kg. In this context, the reference is meant to a single metal component that is being replaced by a hybrid component that serves the same basic purpose. In the example housing of FIGS. 1-3, this would comprise each one of the housing sections 4, 5. Further, application of the techniques would generally be practical and substantial if the resulting replacement composite component is at least 10% lighter, often at least 15% lighter and usually at least 20-45% lighter or more, than an all metal component for the same application.

Often, the resulting metal configuration will have thick/thin metal sections (for example alternating) as needed for managing the load during use. This will be an issue of strength characteristics of the metal and the operational needs of the component. When the thick/thin section are oriented around a central axis, for example as described for above for hub sections 40, 50 and 95, the thin sections will, in many examples, have thin sections no more than 85% as thick as the adjacent thick sections, usually no more than 75% and sometimes no more than 60% as thick.

The techniques applied to provide for determination of the desirable housing component can be a variety of engineering techniques now known or later developed. For example, currently available load mapping techniques, using computer modeling, can be used to determine where load-bearing occurs in the resulting construction (i.e. the construction existing prior to improvement, and/or the proposed alternate improved construction) and the amount of load that may occur. When the analysis concerns a current construction (for example a current housing) prior to improvement, the engineers can define particular load levels above which it is desired to maintain metal or a portion of metal and below which it is desired to either have less metal or no metal, depending on the system of application.

The designer can implement anchoring sites in the resulting metal component as appropriate for the intended overmolding operation.

Designing of the molded sections is a matter of ensuring that the resulting plastic (or plastic composite) becomes distributed where needed, for example, to accomplish the following:
(a) To close the construction if portions have been left open due to removed metal and closure is needed;
(b) To provide, for example in combination with some metal, adequate strength in regions of lower load;
(c) To ensure that the plastic composite appropriately engages the anchor site(s) if any; and,
(d) In some instances, to optionally provide an outer surface of the molded plastic portion(s) having any desired surface features, for example such as: design features; and, equipment features that do not need the strength of metal but which can provide advantage in installation in use.

Of course, the plastic section(s) should be designed such that a convenient application operation for applying the plastic to the metal component can be undertaken.

From a review of FIGS. 4-9, it can be seen that the example depicted reflects implementation of all of the above techniques.

In general terms, computer modeling approaches can be used for determining, in the structure, which metal, in the model, can be removed or be provided thinner. A variety of computer programs and modeling approaches can be applied. An example is the modeling conducted by computer programming under the mark “Optistruct” available from Altair. For such modeling one can determine through topological mapping where higher loads or stresses are borne by the structure. These regions should be retained metal in a sufficient amount to manage the forces of concern. In other regions, one can remove metal completely or partially, with the model demonstrating that the loads will still be sufficiently borne by the overall structure.

In those applications of the techniques described herein, in which a previously existing metal component is replaced with a metal/plastic hybrid, the original all metal component can be subject to a topology optimization process to identify primary load-bearing areas experiencing high loads and secondary load-bearing areas experiencing low loads or no load. Of course, the modeling can take an analogous path even if there is no prior part. This topology optimization, again, can be conducted using computer modeling and optimization software. Such software can used advanced methodologies to identify load paths in the component and output a topographical or organic structure having material only in areas where load is present. In a typical application, this analysis can be conducted independent of material analysis. That is, the topology optimization can be used to identify load paths in the component, independent of material properties. The result is that the load paths will highlight where material is or is not required to carry primary load. As a result of identifying the load paths, the task of defining the shape of a component having a high load-bearing structure where required, is facilitated.

The topology optimization can include applying constraints, to exempt selected portions of the component from analysis. For example, portions comprising wear surfaces, attachment points or regions for various types of contact areas for equipment, can be exempted and retained in the high load (metal) material. This will be a typical approach in many instances.

Detailed topology optimization can be applied to divide the representation of the component into discrete elements. This can make it easier to optimize the component structure shape and distribution, given space constraints in which the component will be used. The topology optimization may also include assessing changes to the space constraints, scaling of different loading scenarios, and/or adjustments to the mass of the component. The resulting component topology may undergo additional processing during topology optimization to, for example, obtain iso-surface contours of density plots. In general, without specific steps used for the topology optimization, the object is to obtain, as an end result, a three-dimensional model of the component with a full understanding of where load-bearing occurs.

Typically, the process will also include structural optimizations that take a three-dimensional model of the component and analyze it with respect to specific structural and manufacturing requirements. In this step, the product and material performance requirements for the component are considered. The structural optimization can include evaluating and improving the structural efficiency of the component design and minimizing the mass of the component will still be meeting desired structural requirements. For example, the structural optimization methodology may be applied to optimize (or at least approach optimization) of the stiffness, size, shape, strength, durability, manufacturability, application feasibility and/or material selection of the component and balance these competing requirements against each other. For components having complex structures and/or product requests, multi-domain, multi-material optimization approaches can be used.

Thus, in general, the techniques involve creating a load map for the component, and studying the load map to determine which regions carry less or relatively little load and which carry more. The component is then modified in accord with these observations.

In addition, once the strength characteristics of the hybrid comprising the plastic and metal together is understood, modeling can be used to evaluate the characteristics of the resulting hybrid part, after the plastic is added.

As indicated above, in general, as the metal portion of the resulting hybrid component is being designed, additional factors will be implemented in the final design once the load-bearing sections, and other key metal sections are defined. These additional features can include: introduction of adequate anchor sites for molded plastic composite features; and, configuration for desirable manufacturing/machining; for example, development of a configuration that can be readily cast and, when necessary machined. Example features to accomplish this can be understood by a review of FIG. 6, discussed above.

### III. Choice of Plastic Composite Materials; Preparation of the Hybrid Structures

### A. Modeling

In addition to determining the structural requirements, material choices for selected portions of the resulting structure need to be made. Typically, with applications according to the present disclosure, the high load-bearing portions of the structure will comprise metal, for example, iron or steel (sometimes aluminum or other metals). Often the components will be cast metal, but alternatives are possible.

The load-bearing analyses referenced above will also provide for an understanding of the structural characteristics that are needed in all portions of the hybrid component, and not just the metal portions. Typically, even the plastic composite portions of the composite will have some load-bearing property that is understood to be incorporated into the product design. Thus, in some instances, the structural optimization step can be conducted iteratively to refine the hybrid component model as metal portions are modified and plastic composite portions are added. The material collection step will often involve consideration of stress level, compliance and natural frequencies of the materials considered, for both the metal portion(s) and the plastic composite portion(s) of the overall hybrid structure.

In general, selection of the plastic composite material is conducted by material selection steps that including selecting the plastic composite material formulation from materials that can handle loads experienced by a resulting portion of the structure, and which have sufficient chemical and thermal resistance to withstand the operating environments involved. Usable plastic materials include, but are not limited to, particle reinforced plastics and fiber reinforced plastics. The modeling process can incorporate any number of modeling techniques that can predict properties, such as properties relating to strength, mechanical properties, elastic properties, electrical properties, hydroscopic properties, and structural and mechanics, etc. The modeling can also use simulations of the materials respond to various manufacturing processes and modeling failure modes of the material. The plastic modeling techniques include numerical methods (e.g. finite element modeling, control volume method, finite difference method, Monte Carlo simulation, molecular dynamics studies, peridynamics, etc.) and analytical methods, such as semi-empirical modeling.

It is noted that the resulting plastic/metal hybrid component may have a relatively complex geometry, making it potentially challenging to select an appropriate plastic composite material having desired properties in the material selection step. Generally, the properties of the plastic composite material can vary greatly depending on the material used for the matrix and the material and physical structure of the filler (i.e. reinforcement). These properties can be taken into account during material selection. The component can be considered as possessing thin zones, moderate zones, and thick zones, based on various transfer functions. The dimensions for each zone can be selected based on, for example, existing knowledge of changes in material properties as the dimensions change. For example, a thin zone may a zone that reflects dimensions where a fiber reinforcement in the plastic is forced in alignment within a plane, making the resulting plastic composite act as a isotropic material. A moderate zone may reflect dimensions where the fibers have some freedom to move in random direction, but remain somewhat aligned to form a quasi-isotropic material. A thick zone may be a zone where fiber reinforcement in the plastic is allowed to arrange randomly. These varying material properties for the same plastic materials can predict fiber orientation within different areas of the component, and the information can be incorporated into the material selection step.

As an example, transfer functions themselves can be based on, for example, the physical dimensions of selected areas of the component, the effects of the manufacturing process such as the process flow rate or change flow rate in the molding of the material and the plastic composite properties. Once the component has been divided into zones, the method may include selecting one or more of the transfer functions described above, to taking the effects of fiber volume fraction, fiber length and fiber orientations in the plastic material, to model material properties in each zone. This step may involve applying fiber volume fraction, fiber length and fiber orientation into account via micromechanics theories (for example Halpin T89; Halpin-Pagino; Mari-Tanaka; Classic Laminate theory; shear log model; composite cylinder model) to homogenize the properties of a given zone. In some instances, this step can involve generating constitutive constants that can be used in finite element analysis or other types of analysis.

Next, the homogenized zone properties would be analyzed through approaches such as finite element analysis to model stress/strain fields in the component and apply performance criteria to generate microscopic material properties. Possible performance criteria may include Puck; Tsai-Wu; Von Mises and other criteria.

The various steps described above can be conducted iteratively to classify the zones and obtain their corresponding properties at higher resolutions, although this is optional. Also, they can be conducted in the linear range of the plastic material, averaged into the non-linear range of the plastic material and/or be conducted separately and distinctly in both the linear and non-linear ranges.

The overall component design can be optimized by reiterating the various steps over the linear and non-linear ranges to iterate the grid construction zoning, constitutive equations, and performance criteria.

Typically, the models generated will be based on an assumption that there is perfect bonding between the metal and plastic composite material, since material failure is not allowed in the hybrid component. However, to predict performance of the hybrid component more accurately, the modeling process may include a step that models a failure mode in the metal/plastic interface (i.e. debonding, or delamination) to provide more accurate performance prediction of the hybrid component. The model can be applied in a manner that reflects the behavior of various joining methods so the results can be incorporated into the hybrid component model. This allows the metal-plastic joining method to be tailored to obtain a desired interface strength with minimal experimentation. Possible joining methods include, for example: injection overmolding (where the metal construction has anchor sites, for interlocking with the plastic material during a molding); metal overmolding (where the metal frame is coated with a polymer, which is then ultrasonically welded); adhesive bonding (where the metal and plastic are attached together with adhesive) and clinch joining (where portions of the metal are deformed so that it locks around a portion of the plastic). Of course, other joining methods (and combinations of methods) are possible.

Failure mode modeling involves application of an interface model to predict failure, such as debonding or delaminating, between surfaces along the metal/plastic interface. The model interface can be generated from a traction-separation law. The traction-separation law indicates the amount of traction between the separated surfaces when the metal-plastic joint is under load; the traction between the surfaces varying depending on the particular traction-separation law corresponding to the specific metal and plastic (composite) material as well as joining methods and interface characteristics.

A method that can be used to generate traction-separation law is through molecular dynamic simulation. With such an approach, the input data includes information on the positions, velocities, and interatomic potential of the metal-plastic structure. Molecular dynamic simulations are run on this input data, and the resulting output is the traction-separation law. For example, a molecular dynamic simulation may include modeling grain boundaries in the metal to simulate intergranular fracture.

Another method of generating the traction-separation law is via cohesive zone modeling, which uses experimental data to model the metal-plastic interface. Generally, the adhesive zone models describe a relationship between interfacial force and a crack opening displacement. The fracture process zone can be implied to be a zone that initially has zero thickness and is composed of two coincident cohesive surfaces: a metal surface and a plastic surface. When a load is applied to the surfaces, the surfaces separate and the traction between may vary according to its specified traction-separation law, which can be determined experimentally or through simulation. In certain approaches, four parameters are used to find the cohesive zone model: tₙ (maximum normal traction); tₜ (maximum tangential traction); σₙ (normal separation distance); and, σₜ (maximum separation distance); tₜ and σₜ being shear parameters, while tₙ and σₙ are normal parameters.

Of course, samples can be made using various combinations of matrix materials, reinforced materials, filler materials and/or fiber structures to test the properties of the plastic composite materials. The polymer composition and reinforcement will affect the mechanical thermal properties of the overall component. For example, fiber orientation and an anisotropic polymer may affect thermal expansion and mechanical properties of the composite. Since composite materials can be expensive, additional analysis may be conducted to select the most cost effective materials and manufacturing methods.

For the shear parameters, tₜ and σₜ and the normal parameters tₙ and σₙ, the method may include conducting a known double lap shear test, tensile test, and double cantilevered beam text on various metal-plastic specimens to obtain experimental data on the interface response. The method can include simulating the same double lap shear test, tensile test and double cantilevered beam test on models of the metal-plastic specimens. The simulation may be conducted by, for example, generating one or more finite element analysis models in the specimens. The simulated cohesive zone model parameters can be adjusted on the experimental generated. The experimental and/or simulated cohesive zone models are then used to generate a simulation to obtain the traction-separation law. The traction-separation law(s) is then used to generate the interface model for predicting joint failure for a given load. Additional tests, such as cyclic fatigue testing, creep, tear strength, modulus, thermal properties, hygroscopic, and chemical resistance may be both experimentally test and simulated, so that the interface model reflects these properties.

### B. Useable Polymers; Reinforcements

The polymer chosen for the molded (plastic), i.e. composite, portions can be of a variety of types, depending on the application. The polymer can be applied in a variety of manners to the metal structure depending on the application.

For many applications the technique used to apply the plastic to the metal will be compression molding. The plastic composite, in many instances, especially when the component is a housing, will comprise an overmold, i.e. material molded to an exterior of the metal component.

In general, in compression molding, a press is used to compress a dough of resin containing material in place, at elevated cure temperature. A die mold is used to shape the material desirably. In many instances, the resin composite chosen will be reinforced, for example fiber reinforced.

In general, plastic resins can be either thermoset resins or thermoplastic materials. Either thermoset resins or selected, thermoplastics can be used in some applications. Thermoset resins require an addition of curing agent or hardener and flow into a mold location, followed by curing step to produce a finished part. Once cured, the part cannot be readily changed or reformed, except for mechanical machine finishing. Example thermosets, useable with techniques according to the present disclosure include, but are not limited to: polyesters; vinyl esters; epoxies; polyurethanes; phenolics and amine resins; bismaleimides; and, polyimides. Alternatives are possible, however.

Of the various thermoset plastics widely used, (in industry today) ones that would often be chosen for many applications according to the present disclosure, would be epoxies. Epoxy compounds are often the reaction product of an epichlorohydrin and bisphenol-A. Such epoxy compounds are sometimes referred to as “glycidyl compounds.” The epoxy molecule can be expanded or cross-linked with other molecules to form a wide variety of resin products. These resins range from low viscosity liquids to high molecular weight solids. Typically, ones used with techniques described will be high viscosity liquids. They are obtainable from a variety of sources.

The resin system, during cure, typically includes a curing agent or hardener. These compounds control the reaction rate and determine the performance characteristics of the molded plastic material. Since the compounds act as catalysts for reaction, they must contain active sites. Some of the commonly used curing agents in the advanced composite industry are aromatic amines. Two examples are 4,4-methylene-dianiline (MDA) and 4,4-sulfonyldianiline DDS). A variety of other curing agents can be used, however, including aliphatic and cycloaliphatic amines, polyaminoamides, amides and anhydrides.

In some instances, it is anticipated that polyurethanes will be used to from the plastic portion of the component. Polyurethanes are formed by reacting a polyol component with an isocyanate compound. Typically tolune diisocyanate (TDI); methylene diisocyanate (MDI) or hexamethylene diisocyanate (HDI) is used; although alternatives are possible.

Other useful resins include phenolic and amine resins.

Thermoplastic resins, again, can be used for the plastic component. An example is polyethylene sulfide (pps).

Thermoplastic resins are typically supplied as non-reactive solids that require heat and pressure to form a finished molded structure. Thermoplastics can go through melting/freezing cycles repeatedly. This quality makes them recyclable. Thermoplastics are sometimes classified by the structure of the polymer changes that comprise them. In a liquid state, the polymer molecules undergo entanglements that prevent them from forming regularly arranged domains. This state of disorder is preserved in the amorphous state. Thus, amorphous plastics, which include polycarbonate(s), polystyrene(s), acrylonitrile-butadiene-styrene(s), and polyvinyl chloride(s) are made up of polymer chains that form randomly organized structures.

Under suitable conditions the entangled polymer chains can disentangle themselves and pack into orderly crystals in the solid state, known as semi-crystal polymers.

Fiber reinforcement in the resin will be typical, and can help provide the structure performance required for the final hybrid part. Fibers or filaments are available in many chemical types and forms, and are the primary contributories to the stiffness, strength, and other properties of the plastic portion of composite material. Examples of useable fiber material include: fiberglass; aramid; carbon; polyester; and, vectran fibers. However, other fiber types can be used.

Often, the reinforcement chosen will be fiberglass. Fiberglass is mostly silicon dioxide processed with platinum and rhobidium. Typically, textile (continuous filament) glass fibers would be used. Such fibers are typically die-drawn rather than spun.

High performance reinforcement materials can be used, such as carbon/graphite fibers.

Aramide fibers are highly heat resistant and strong synthetic. These can be used, if the circumstances warrant.

The fibers can be used in a variety of forms. For example, rovings, chopped fibers and/or fabrics can be used. The term roving refers to a collection of untwisted strands or yarns. A strand is a collection of continuous fiber filaments and yarns are filaments of strands twisted together. Roving is supplied on a weight basis with a specific filament diameter for a single fiber roving (one continuous strand) or multi-fiber roving (numerous strands). Roving is also used to produce mats, woven fabrics, braids, knitted or hybrid fabrics, and other reinforcing materials.

The reinforcements can be provided as mats, woven fabrics, knitted fabrics, or braided fabrics, if desired. They can also be provided as rovings or chopped fibers.

Sizing will typically be used with the fibers, especially if glass fiber is used, to provide mixing with the resin. Sizing helps bind the fibers to the resin matrix. Lubricating oil in the sizing is typical.

A variety of processing methods can be used to provide the polymer composite (resin plus reinforcement) application to the metal structure, to form the resulting hybrid (plastic plus metal combination). Layette molding, spray molding, compression molding, transfer molding, injection molding, pultrusion and filament winding are examples. Typical approaches with many applications of the present disclosure, as indicated above, will involve compression molding or injection molding techniques.

### C. Processing Methods to Construct Hybrid Structures

A variety of processes can be used, with techniques according to the present disclosure to create the metal/plastic hybrid composite. As indicated, the techniques often include: injection molding; compression molding; and/or extrusion. However, also as indicated, in some instances other techniques can be applied.

In some instances, hand lay-up molding is used. Hand lay-up molding is a method of laying down fabrics made of reinforcement and painting on the matrix resin, layer-by-layer, until a desired thickness is obtained. Thus, a fabric, for example, impregnated with resin can be applied to the metal structure, with additional resin application until the desired thickness is obtained.

Spray-up molding can be used in some instances. Here continuous fiber is fed into a cutter, chopped and then sprayed with a stream of resin mist and catalyst onto the metal substrate.

It is expected that in many applications, compression molding will be used. In compression molding a press is used to compress a dough of resin and fiber mixture onto a substrate, typically at an elevated cure temperature. With the compressive force, the void content is lower than the ordinary atmospheric pressure processing method. A matched die mold allows shaping of the plastic.

Transfer molding is usable in some instances, and is an improved version of compression molding. Here, the fiber/resin mixture is transferred from the reservoir into the mold cavity by a press. Typically, such an approach will use only short fiber reinforced resins.

Resin transfer molding, another usable technique, is similar to ordinary transfer molding, except that only the resin is transferred molded into the mold cavity, in which fabrics would have been placed beforehand.

Injection molding is a well-known approach for processing short-fiber reinforced thermoplastics, and can be used in some applications according to the present disclosure. Here, the fiber resin is fed into a hopper and transferred into a barrel. The materials soften by heat transfer from the barrel wall. At the same time, a screw rotates to apply a high-shear process to further heat the material and fill the barrel. The molten material is collected from the screw and then injected, with high pressure, into the mold cavity.

Pultrusion techniques can also be applied in some instances. Here, a bundle of fiber rovings is passed through a wet resin path, squeezed into a desired shape, passed through a heated die, and cured into a final construction. This construction, of course, can then be applied to the metal. A related approach, filament winding, involves winding resin-wet roving on a mandrel, placing the mandrel in an oven and curing to a particular configuration. This can be used to form plastic portions of the eventual composite, which can then be added to the metal.

### D. Preparation of the Metal Surface for Application of Plastic Composite

As indicated above, the metal surface can be made rough, to facilitate securing the plastic thereto. It can be roughened by treatment such as abrasive blasting, if desired. Also an adhesive such as a siliane adhesive can either be applied to the metal surface before contact with the plastic resin, or be included in the plastic resin to facilitate adherence.

### IV. A Working Example

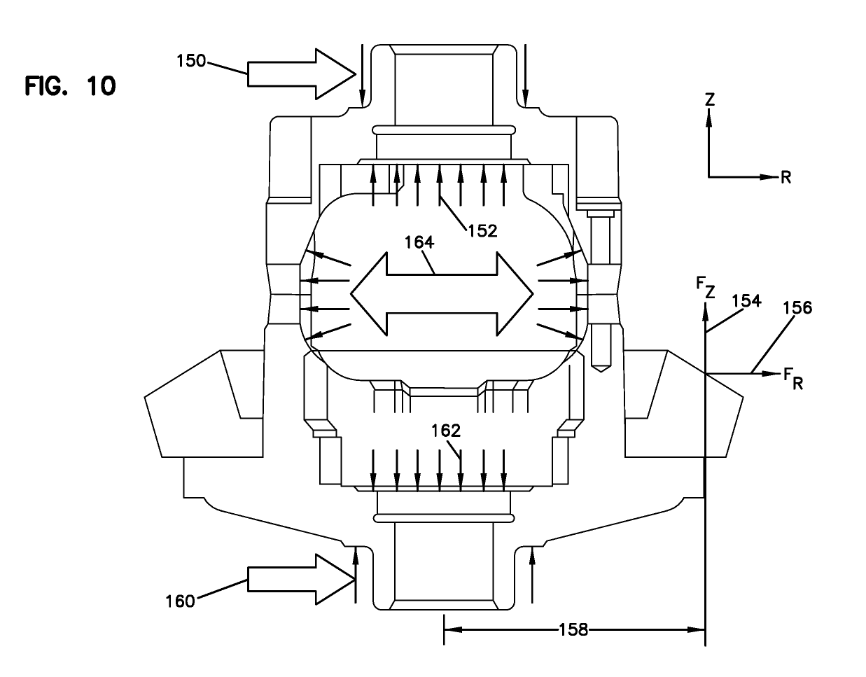

In this section, a connection with FIGS. 10-16C, steps undertaken and development of a working example are provided.

For the example, the technology was demonstrated on a current 6-pinion differential housing, weighing approximately 8 lbs., current material choice being cast iron. There is a rotating group within the housing. The allowable package space, application conditions (chemical exposure and operating temperatures), and magnitude and direction of the loads were identified, see FIG. 10.

Referring to FIG. 10, at 150 a bearing preload determined at 4000N is indicated. At 152, a side gear separating force of 3300 N-m is indicated. At 164 a pinion gear separating force of 3055 N is indicated. At 154 a ring gear axial force F_{z} of 17064.49 N is indicated. At 156 a ring gear radial force Fᵣ of 20516.49 N is indicated. At 162, a side gear separating force of 3300 N-m (Newton-meters) is indicated. At 160 a bearing preload of 4000 N is indicated. A ring gear pinch radius is indicated at 158. For the system a total axial torque of 330 N-m is determined.

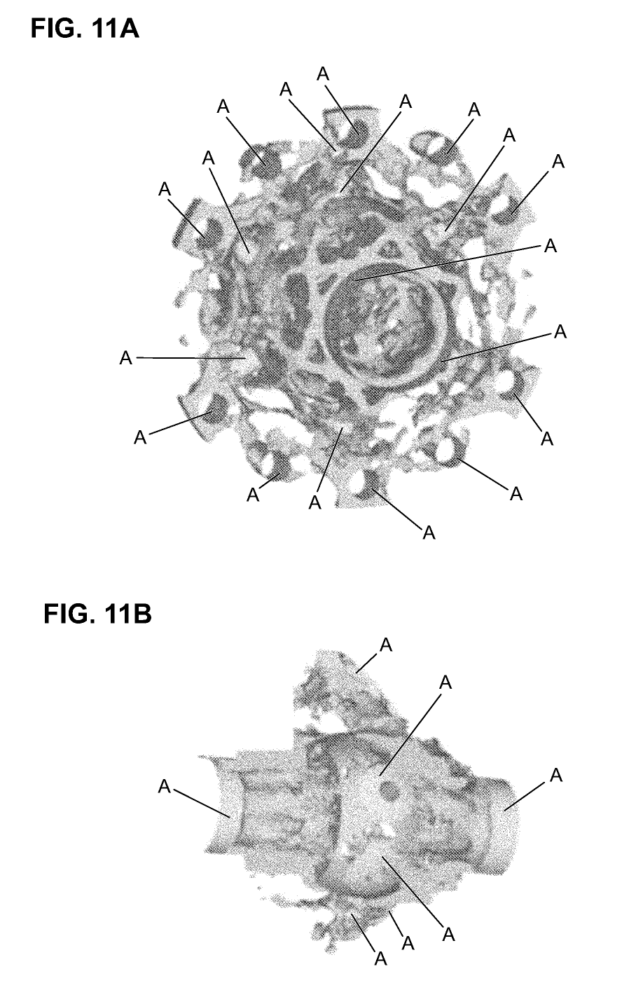

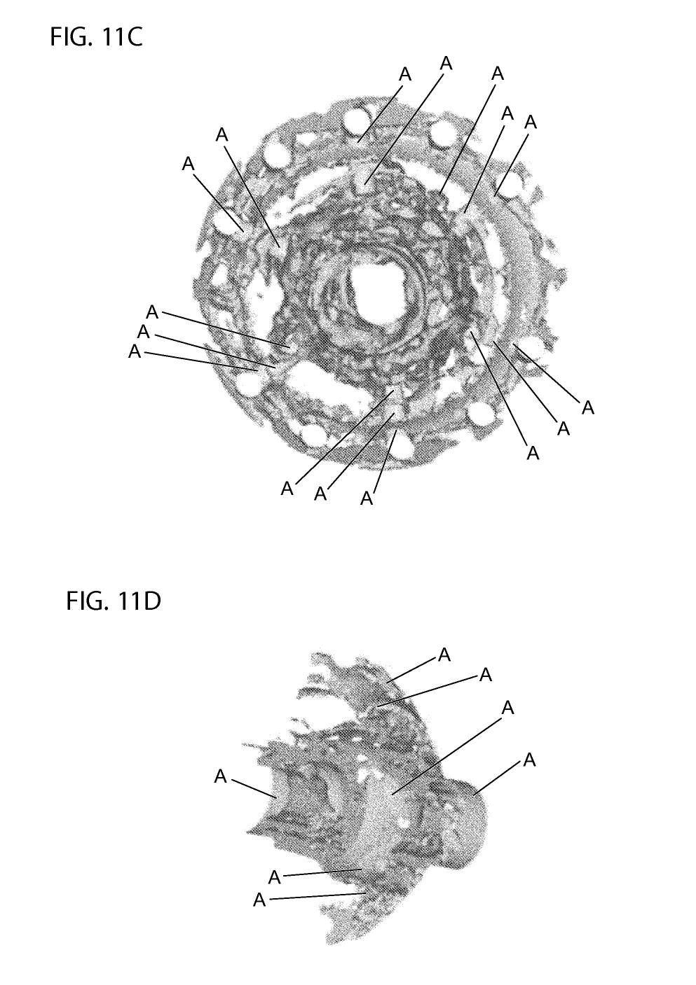

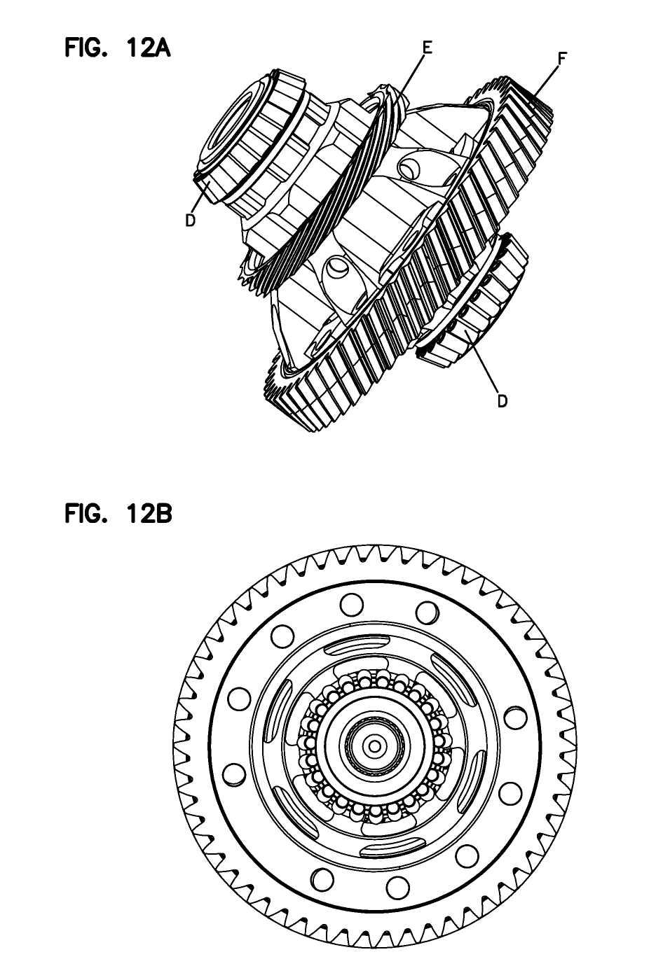

An initial step was to apply the current 3D CAD data of the differential housing assembly to create a representation of the available package space. Next HyperMesh (Altair software) was used to discretize the package space with tetrahedral finite elements. Constraints were applied at the differential housing attachment points (assumed to be carryover) and static loads were applied at the center of the gears using the existing loads cases. These loads were then used by OptiStruct (Altair software) to develop the optimal distribution of the structure within the available package space, irrespective of material properties. Areas identified as having critical dimensions or as wear surfaces were exempt from the optimization process. Areas along the load path were identified and subsequently areas that were not required to carry load were removed. The result was two schematic structures (FIGS. 11A-11D) which were further interpreted into three design concepts (FIGS. 12A-14B).

Referring more specifically to FIGS. 11A-11D and 12A-14B, the following can be observed. Two views of a first schematic structure are shown in FIGS. 11A-11B. The regions indicated at A are regions kept in metal that were not part of the optimization. The other regions indicate load distribution (and blank spaces to little load). A second schematic structure is indicated in FIGS. 11C and 11D, in two views and not metal. Again, the regions indicated at A are regions exempted from the analysis and metal. The other regions, again, are regions of load distribution.

The schematic structures described above in connection with FIGS. 11A-11D, then, show the designer where the load distribution was to occur. Based on these, design concepts for the hybrid construction could be developed, the optimization study having shown where the load distribution would occur and where it would not occur in the model.

A first resulting design concept is indicated in the two views of FIGS. 12A and 12B. In FIGS. 12A and 12B, a differential housing is depicted, with selected bearing rings and gear structure thereon. This unit generally corresponds to the housing described above in FIGS. 4-9. At D, FIG. 12A, are provided bearings (output bearings). These are typically pressed on. The bearings D interface a housing, to provide a low friction running surface and to control position. It is desirable that the portions of the housing on which the output bearings are positioned be metal. This is accommodated in the example assembly described.

At E, FIG. 12A, a speed ring is depicted. It is slipped-fit or pressed on. The speed ring is a speedometer to measure how fast the differential is spinning. It is also desirable that portions that must support the speed ring E be metal. This is accommodated in the ultimate design selected. At F, is positioned a ring gear. It is bolted onto the housing. The ring gear receives output from the transmission and provides input to the differential. It is desirable that the portions of the housing, on which the ring gear F is secured, be metal to bear the appropriate loads. This is accommodated in the design.

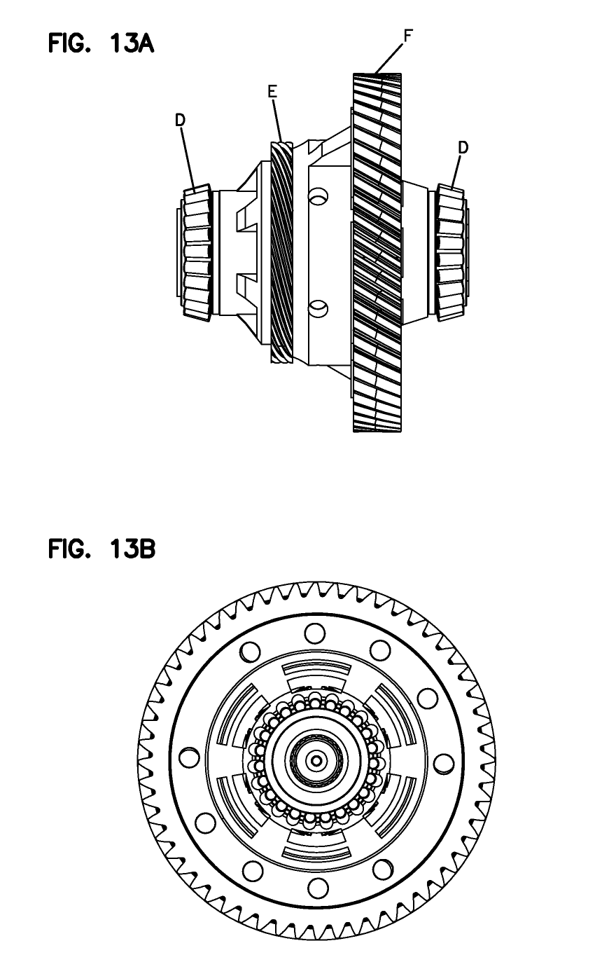

A second design concept is indicated in the two views of FIGS. 13A and 13B. It is noted that in FIG. 13A, analogous rings to rings D, E and F are shown positioned on the concept.

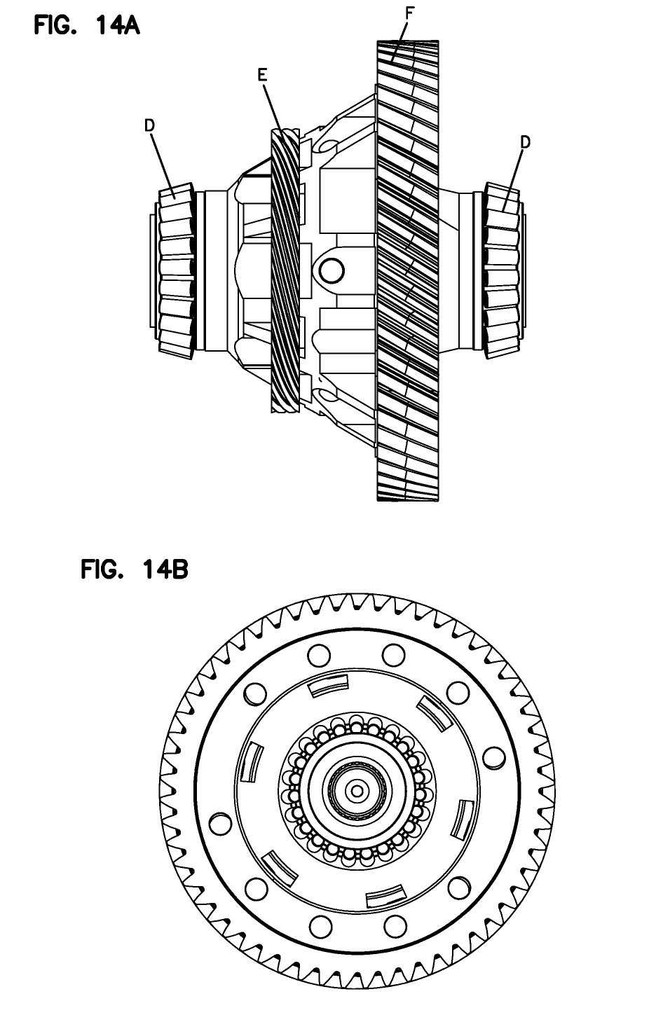

The third design concept as indicated in the two views of FIGS. 14A and 14B. It is noted, referring to FIG. 14A, that analogous rings to D, E, and F, FIG. 12A are shown positioned on the concept.

The three design concepts were further evaluated based on two material extremes. The first being the current production cast grey iron and the second being a fiber reinforced thermoplastic, injection molded. Down-selection focused on the following criteria: weight reduction, preliminary structural analysis, and application feasibility. Application feasibility is primarily the ability of the housing to allow for axel fluid to flow through the system which provides the required cooling of the rotating group allowing for extended life durability requirements. Concept 1 (FIGS. 12A/12B) was selected for the further optimization based on structural analysis.

The next step was to select a material and process. The following decision criteria was used for material selection—high tensile strength and modulus, ease of processability for complex geometries, and the cost to process. It was based on this information that a PPS (polyphenylene sulfide) thermoplastic reinforced with 45% carbon fibers 1 inch in length was selected. The additional benefits of using this combination of fiber and material is the thermal stability, low thermal expansion of the material that closely matches that of steel (the material for the metal frame), and the ability to process using compression molding, a process which lends itself to high volume applications that can be complex in shape. The material was chosen Celstran LFRT obtained from Ticona.

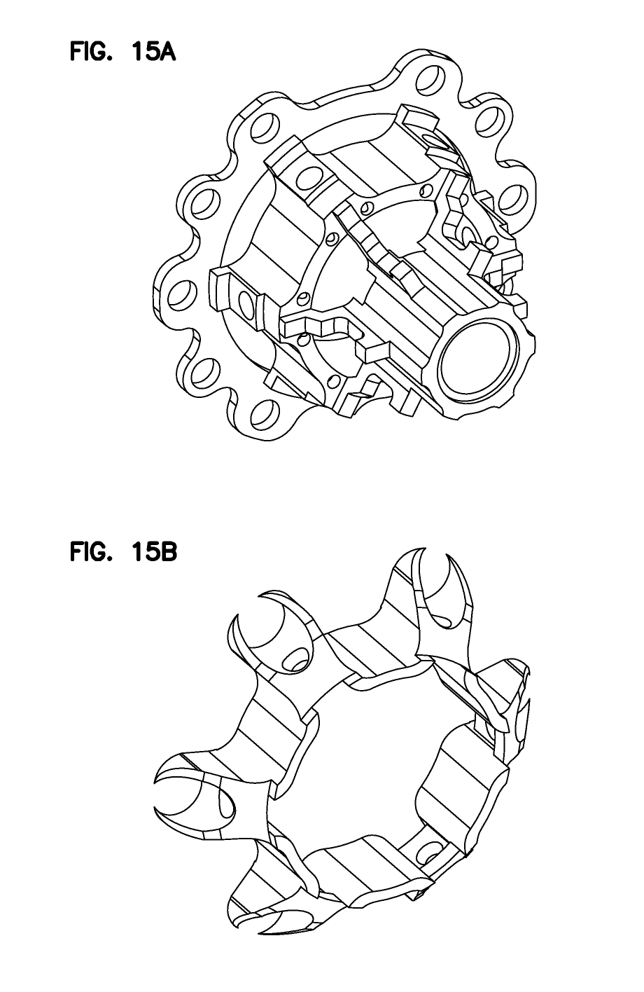

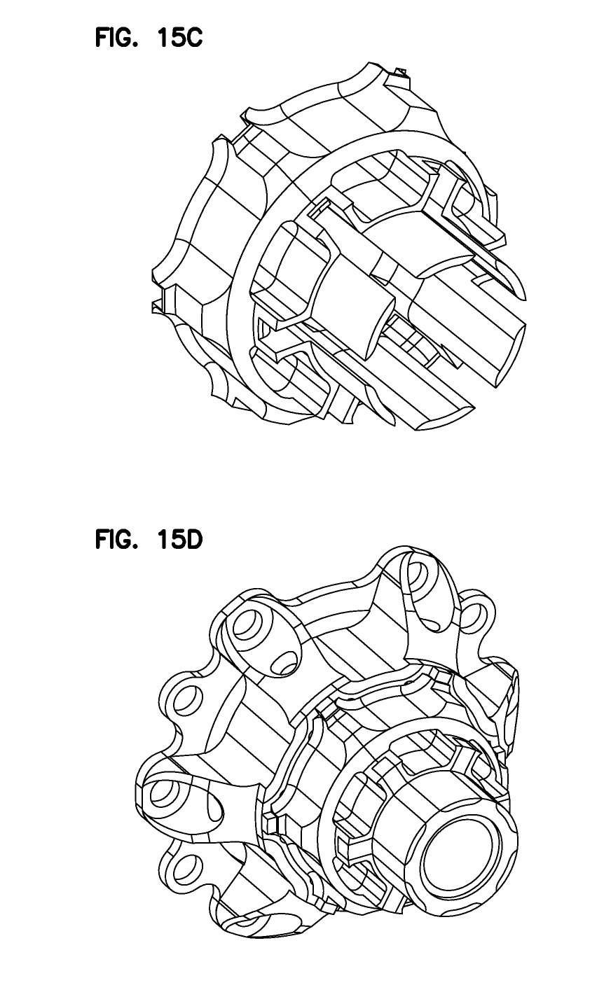

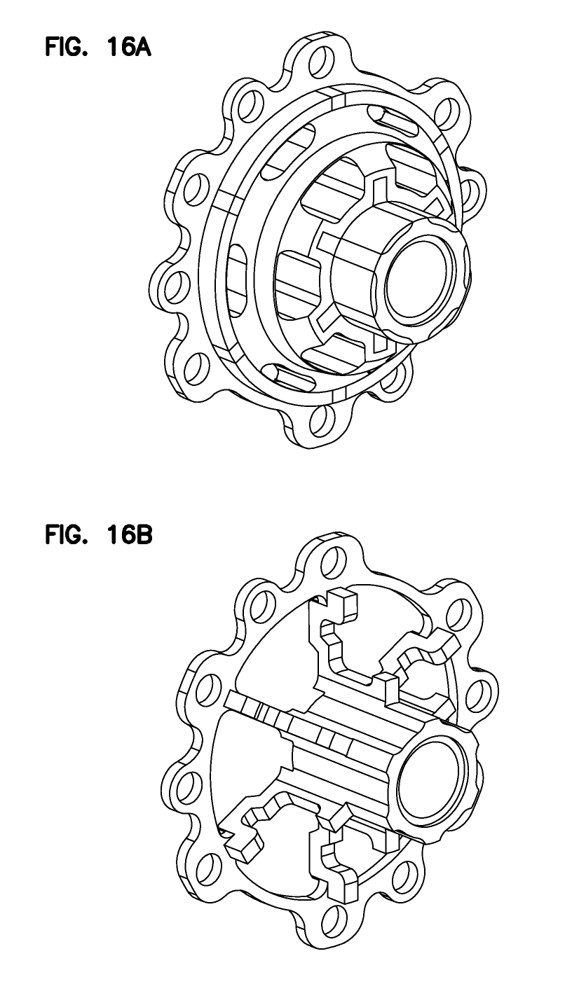

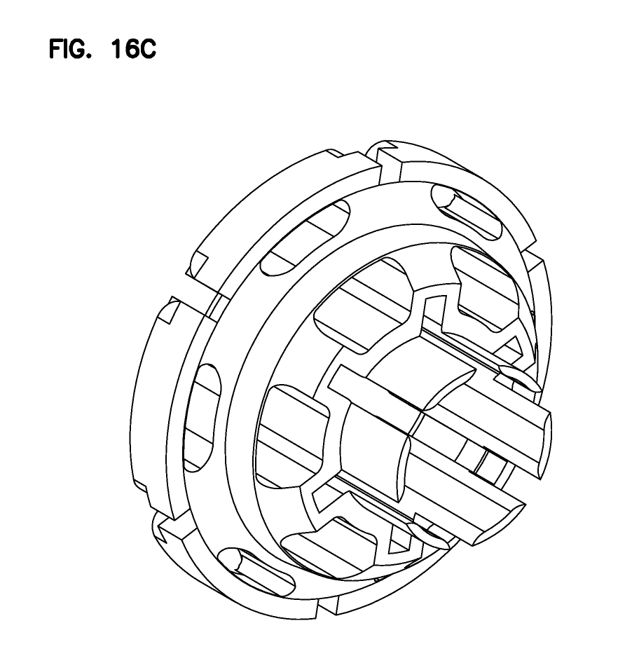

Prior to additional structural optimization, the design was divided into a skeletal metal frame and a composite overlay. As the goal of the technology was to reduce weight, the focus was to minimize the metal frame as much as could be tolerated and still provide the strength and stiffness needed to meet the load requirements provided at the onset. Regions requiring a wear surface with the rotating group, the areas that would be needed to support the bearing, the ring gear, and the speed gear, and the regions where dimensioning was critical such as the diameter for the shaft and the bolt holes for the ring gear, were all identified as requiring a metal component. The remaining regions were eligible for composite materials. Based on these assumptions the design was divided into two parts, a first illustrated in FIGS. 15A-15D and a second, FIGS. 16A-16C. More specifically, in FIG. 15D, one of the two housing sections is depicted. It will be formed from a metal section as indicated in FIG. 15A, and plastic composite sections in FIGS. 15B and 15C. In FIGS. 16A-15C: the component in FIG. 16B will be metal; the sections in 16C would be the plastic.

A next step was the FEA (Finite Element Analysis) of the hybrid structure, meaning with both the steel skeleton and composite overlay. The model was constrained were the shaft passes through the housing. A safety factor of 2× was applied to the composites modulus. The assumption was to account for material fatigue that could occur during the application due to chemical, thermal or cyclic exposure. FEA was also used to identify the maximum shear stresses. This value was also used as a threshold for selection of various mechanical and chemical joining techniques.

### V. Table of Information Regarding Example Systems of Application

In the following table, some example applications of the techniques described herein are provided, by way of defining certain existing systems, the housings of which, or certain portions of which, can be made from hybrid components is described herein. The examples include transmission housings; transmission gears; and, differential housings.

In the detailed description and configurations discussed above, examples relating to a differential housing are provided. The transmission housing examples would typically involve a housing that contains equipment but is not itself required to support exteriorly positioned gears, bearings on the like. With transmission housings, it is expected that the plastic will generally be deposited on an exterior of the metal part or housing, although in some locations it may close otherwise open areas.

Also identified are transmission gears. In an application to form a transmission gear, from a hybrid component, selected portions of the gears (but not the teeth) can be provided with plastic in forming the hybrid component.

The references to loads and torques of “maximum” values are meant to values that the replacement component would at least need to meet, as a minimum, in order to be an acceptable component. That is, the specifications for operation of the equipment would typically require a part to manage a maximum load or torque of at least the amount identified, in many applications.

| | | | | | |
|---|---|---|---|---|---|
| Appli- | Compo- | | Weight | | |
| cations | nent | Material | (kg) | Loads | Torques (N-m) |

Transmission Housing

| | | | | | | |
|---|---|---|---|---|---|---|
| Medium | Main | Alu- | 15 | Kg | Max load of | Maximum Input |
| Duty | Case | minum | | | 63,000 N | Torque = 895 |
| | | | | | | N-m |
| Heavy | Main | cast | 62 | Kg | Max load of | Maximum Input |
| Duty | Case | iron | | | 45,900 N | Torque = 2508 |
| | | | | | | N-m |
| | Rear | cast | 19 | Kg | | |
| | case | iron | | | | |

Transmission Gears

| | | | | |
|---|---|---|---|---|
| Trans- | steel | 100 | kg | drive shaft (1222 |
| mission | | | | up to 5394 N-M) |
| Gears | | | | Output shaft |
| | | | | Torque (6324 up |
| | | | | to 23726 N-m) |

Differential Housing

| C510/ | cast | 1.5 to 5 kg | | 3000 N- | 300-5000 N-m |
|---|---|---|---|---|---|
| FWD | iron | | | 20,000 N | |
| RWD | cast | 36 | kg | | up to 16,000 N-m |
| | iron | | | | |

### VI. Some Example Observations

### A. Typical Conditions for Applications of the Techniques Described Herein

As indicated above, typically the techniques described herein will be applied when the component being replaced by the metal/plastic hybrid component has a weight to be reduced by at least 10% often at least 15% and usually at least an amount within the range of 20-45%, inclusive, and sometimes more.

Typically the techniques will be applied when the component being replaced by the metal/plastic composite component has metal regions where load-bearing of at least 1000 N, often at least 1500 N, usually at least 2500 N and often 3000 N will occur in operation; and, also has regions where maximum load-bearing of substantially less will occur in use.

It is noted that in some applications, the techniques will be applied not to replace the previously existing metal component, but rather to design a new component. Similar or analogous factors will be present. That is, even though the part does not replace a specific previous part, it would be used in place of a conceptual all metal design, generally in accord with the above.

B. A Housing that Supports Internal Gearing Structure, Etc.

When the component is a housing (for example a differential housing) that is configured as two overall housing pieces including structure for supporting internally positioned gearing pinions, etc., techniques according to the present disclosure, when applied most beneficially, will lead to overall composite housing structure, having characteristics in many instances in accord with the following:
1. Each housing piece will often have a metal flange for mounting to the other mounting piece;
2. The metal portion of the housing will often have a “ribbed” hub structure, i.e. thick longitudinal ribs extending away from the flange in thicker parts of the metal, which parts also include machined portions for mounting components such as pinions.
3. In many instances, the number of thicker ribs will be at least 4, for example 6-8.
4. In some instances, the thicker metal ribs or sections will be “symmetrically” positioned around a central axis of the housing component, i.e. they will evenly radially spaced from one another.
5. In some instances, the thin metal rib sections will have a metal thickness no more than 90% as thick as metal in adjoining thick regions of the metal portion, often no more than 80% as thick, for example 40% to 70% as thick.
6. Regions devoid of metal will be located in selected regions between the ribs, for example adjacent the flange.
7. Opposite the flange end of the metal piece will be a hub end often comprising a 360° metal region.
8. The plastic composite material will be positioned on an exterior surface of the metal piece. The positioning will often be by compression molding or injection molding. The plastic will often be reinforced with chopped glass fiber.
9. When the equipment system involved is a housing, such as a differential housing, selected metal portions of the resulting structure will be configured for engagement with (and support of) various gears, bearings and/or bushings thereon, such as an output bearing(s), a speed ring, or a ring gear.

### VII. Summary Observations

According to the present disclosure, assemblies, methods, features and techniques are described, applicable as (or to form) hybrid components (combination metal and plastic components) for a variety of assemblies. The techniques described are particularly effective in providing hybrid components for load-bearing assemblies that are lighter in weight than typical traditional metal components. The amount of weight savings by comparison to a metal component, would typically be at least 10%, often at least 15%, in many instances, 20% or more.

Many of the assemblies constructed in accord with the principals of the present invention will be housing assemblies, often load-bearing housing assemblies. Examples are differential housings and transmission housings. However, the techniques can be applied in a variety of other applications, including for example, in constructing various gearing arrangements for vehicles, as opposed to merely housings.

Often the load-bearing assembly provided with a hybrid component, involves providing a hybrid component configured with portions to support a maximum load of at least 1000 N, typically at least 1500 N, often at least 2500 N, and in many instances 3000 N or more. Indeed, example applications are described in which maximum loads of at least 10,000 N, often at least 20,000 N, and in many instances, 30,000 N or greater are managed by the hybrid structure(s).

Examples are also described in which portions of the hybrid component are configured to withstand a maximum torque of at least 300 N-m, and in some instances, at least 1,000 N-m, and in certain instances at least 5,000 N-m.

As explained herein, the metal portion of the hybrid component can be formed from a variety of different metals. Typically, the metal will be iron, steel or aluminum. Often, the metal portion of a hybrid component will be a cast metal portion, but alternatives are possible.

The plastic portion of the component can be formed from a thermoset plastic material or thermoplastic material. The plastics will often be fiber reinforced. A variety of techniques for application of the plastic to the metal is described, and can be used. In many instances, compression molding will be a desirable approach.

A variety of usable thermoset materials are described as useable in some applications. Examples include polyester(s); vinyl ester(s); epoxy or epoxies; polyurethane(s) penolics and amine resins; bismaleimides; and, polyimides.

A variety of usable thermoplastic materials are described. Examples include polyethylene sulfide(s); polycarbonate(s); polystyrene(s); acrylonitrile-butanene-styrene(s); and, polyvinyl chlorides.

Described herein are example techniques for facilitating securing the plastic to the metal. Anchor arrangements are described to provide for mechanical connection. A particular type of anchor arrangement discussed comprises one or more “anchor bores” through which the plastic can extend during use. Example anchor bores are described in which each end of the bore only communicates with one surface (interior or exterior) of the metal component.

An example housing is described in which, for a component, the metal portion comprises a mounting flange section and a hub section, which are integral with one another. In the example depicted, the flange section or mounting flange section includes a plurality of anchor bores therethrough, for fasteners such as bolts.

In an example described, the hub section: includes radially, alternating, thick and thin sections of metal; includes a plurality of anchor bores therethrough; and (the hub section) is joined to the flange section by a plurality of radially spaced engagement sections having voids therebetweeen. The voids are covered by the plastic, in use.

An example assembly is depicted comprising a housing, which supports one or more of a (ring) gear, a (speed) ring and at least one (in an example, two) bearing(s). In an example, a ring gear, speed ring and two (output) bearings are mounted on an exterior of the differential housing, and are generally secured in position on metal portions of the differential housing.

Also according to the present invention, methods and techniques for designing hybrid components for load bearing assemblies are described. In general, a described method involves defining a corresponding component (for example of complete or nearly complete metal construction) as a subject component; identifying at least one exempt portion of the subject component to be retained in metal; performing a load distribution analysis (optimization) on the subject component; and, based on the results of the load distribution analysis, selecting portions of an eventual corresponding hybrid component to be made of metal and portions to be made of plastic.

An example application is described in which the subject component comprises two housing sections of a load bearing housing assembly; and the identification of at least one exempt portion of the each of subject components (the two housing sections) to be retained in metal includes at least: metal mounting flanges; and, locations where bearings and/or rings (for example output bearings, speed rings, ring gear) are to be mounted.

According to the present disclosure the method designing can be implemented as part of an overall method of constructing a hybrid component. In this instance, the method would further include generating a metal piece corresponding to both the portion of the eventual hybrid component selected to be made of metal and the exempt portion(s); and, the applying plastic to the metal piece to form those regions of the resulting hybrid components that were selected to be made of plastic.

It is noted the method of constructing the hybrid component can be implemented by providing one or more anchor bores in the metal component(s) and providing the plastic in a manner extending through the anchor bores, during application.

It is noted that the application, features, techniques and method described herein can be applied in a variety of manners, and there is no specific requirement that all of the specific features, examples, techniques, etc. described be applied only in the manner and to generate the construction specifically exemplified or described.

What is claimed:

1. A load-bearing housing assembly comprising:
(a) a hybrid component including a metal portion and a plastic portion;
(i) the plastic portion being non-separable from the metal portion; and,
(ii) the hybrid component being configured to support a maximum load of a least 1000 N in a portion thereof.

2. A load-bearing housing assembly according to claim 1 wherein:
(a) the hybrid component is configured to support a maximum load of at least 1500 N.

3. A load-bearing housing assembly according to any one of claims 1-2 wherein:
(a) the hybrid component is configured to support a maximum load of at least 2500 N.

4. A load-bearing housing assembly according to any one of claims 1-3 wherein:
(a) the load-bearing housing assembly is a differential housing and the hybrid component is configured to withstand a maximum torque of at least 300 N-m.

5. A load-bearing housing assembly according to claim 4 wherein:
(a) the load-bearing housing assembly is a differential housing and the hybrid component is configured to withstand a maximum torque of at least 1,000 N-m.

6. A load-bearing housing assembly according to claim 4 wherein:
(a) the load-bearing assembly is a differential housing and the hybrid component is configured to withstand a maximum torque of at least 5,000 N-m.

7. A load-bearing housing assembly according to any one of claims 1-6 wherein:
(a) the metal portion is iron.

8. A load-bearing housing assembly according to any one of claims 1-7 wherein:
(a) the plastic portion comprises fiber reinforced thermoplastic.

9. A load-bearing housing assembly according to any one of claims 1-8 wherein:
(a) the metal portion includes selected voids therein that are closed by the plastic portion.

10. A load-bearing housing assembly according to any one of claims 1-9 wherein:
(a) the metal portion includes at least one anchor bore therethrough that does not communicate with an interior of the metal portion; and,
(b) the plastic portion includes resin that has been hardened after flowing through at least one anchor bore.

11. A load-bearing housing assembly according to any one of claims 1-10 wherein:
(a) the metal portion comprises a mounting flange section and a hub section;
(i) the hub section being integral with the mounting flange section; and,
(ii) the flange section having a plurality of bores therethrough.

12. A load-bearing housing assembly according to claim 11 wherein:
(a) the hub section includes radially alternating thick and thin sections of metal.

13. A load-bearing housing assembly according to any one of claims 11 and 12 wherein:
(a) the hub section includes a plurality of anchor bores therethrough that do not communication with an interior of the housing.

14. A load-bearing housing assembly according to any one of claims 11-13 wherein:
(a) the hub section is joined to the flange section by a plurality of radially spaced engagement sections having voids therebetween.

15. A load-bearing housing assembly according to any one of claims 1-14 wherein:
(a) the load-bearing housing assembly is a housing having a gear mounted thereon.

16. An load-bearing housing assembly according to any one of claims 1-15 wherein:
(a) the load-bearing housing assembly is a housing having a speed ring mounted thereon.

17. A load-bearing assembly according to any one of claims 1-16 wherein:
(a) the load-bearing housing assembly is a housing having at least one bearing mounted thereon.

18. A load-bearing housing assembly according to any one of claims 1-17 wherein:
(a) the load-bearing housing assembly is a differential housing that includes each of a ring gear; a speed ring; and, two bearings mounted on an exterior thereof.

19. A load-bearing housing assembly according to claim 18 wherein:
(a) each one of the: ring gear; speed ring; and, two bearings is secured in position on a metal portions of the differential housing.

20. A load-bearing housing assembly according to any one of claims 1-3 wherein:
(a) the metal portion comprises one of iron; steel; and, aluminum.

21. A load-bearing housing assembly according to any one of claims 1-3 and 20 wherein:
(a) the plastic portion comprises fiber reinforced plastic.

22. A load-bearing housing assembly according to any one of claims 1-3; and 20 wherein:
(a) the plastic portion comprises thermoplastic material.

23. A load-bearing housing assembly according to claim 22 wherein:
(a) the plastic portion is selected from polyethylene sulfide(s); polycarbonate(s); polystyrene(s); acrylonitrile-butanene-styrene(s); and, polyvinyl chlorides.

24. A load-bearing housing assembly according to any one of claims 1-3; 20 and 21 wherein:
(a) the plastic portion comprises thermoset material.

25. A load-bearing housing assembly to claim 24 wherein:
(a) the plastic portion is selected from polyester(s); vinyl ester(s); epoxy or epoxies; polyurethane(s); penolics and amine resins; bismaleimide(s); and, polyimide(s).

26. A load-bearing housing assembly according to any one of claims 1-25 wherein:
(a) the plastic portion is compression molded onto the metal portion.

27. A load-bearing housing assembly according to any one of claims 1-3 wherein:
(a) the hybrid component is configured to support a maximum load of at least 10,000 N.

28. A load-bearing housing assembly according to any one of claims 1-3 wherein:
(a) the hybrid component is configured to support a maximum load of at least 20,000 N.

29. A load-bearing housing assembly according to any one of claims 1-3 wherein:
(a) the hybrid component is configured to support a maximum load of at least 30,000 N.

30. A load-bearing assembly comprising:
(a) a hybrid component including a metal portion and a plastic portion;
(i) the plastic portion being non-separable from the metal component; and,
(ii) the hybrid component being configured to support a maximum load of a least maximum 1000 N in a portion thereof.

31. A load-bearing assembly according to claim 30 wherein:
(a) the hybrid component is configured to support a maximum load of at least 3,000 N.

32. A load-bearing assembly according to claim 30 wherein:
(a) the hybrid component is configured to support a maximum load of at least 10,000 N.

33. A method of designing a hybrid component for a load-bearing assembly; the method including steps of:
(a) defining a corresponding component as a subject component;
(b) identifying at least one exempt portion of the subject component to be retained in metal;
(c) performing a load distribution analysis on the subject component; and,
(d) based on the results of the load distribution analysis, selecting portions of the eventual hybrid component to be made of metal and portions to be made of plastic.

34. A method according to claim 33 further including:
(a) constructing the hybrid component by:
(i) generating a metal piece that corresponds to: the portion of eventual hybrid component selected to be made of metal; and, the exempt portion; and,
(ii) applying plastic to the metal piece to form the region in a resulting hybrid component selected to be made of plastic.

35. A method according to claim 34 wherein:
(a) the step of generating a metal piece includes generating a metal piece having at least one anchor bore therein; and,
(b) the step of applying plastic includes providing plastic in extension through the anchor bore.
